(19) United States
(12) Patent Application Publication
(10) Pub. No.: US 2026/0130058 A1
(43) Pub. Date: May 7, 2026

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., Ltd., Yongin-Si (KR)

(72) Inventors: YEONGHO LEE, Yongin-si (KR); JUNHEE LEE, Yongin-si (KR); JINSU LEE, Yongin-si (KR); CHOONGYOUL IM, Yongin-si (KR); EUNJE JANG, Yongin-si (KR); BEOHMROCK CHOI, Yongin-si (KR); SEONG-YONG HWANG, Yongin-si (KR)

(21) Appl. No.: 19/369,868

(22) Filed: Oct. 27, 2025

(30) Foreign Application Priority Data
Nov. 1, 2024 (KR) 10-2024-0153621
Jun. 5, 2025 (KR) 10-2025-0074074

(51) Int. Cl. H10K 59/122; H10K 59/12; H10K 102/00

(52) U.S. Cl. CPC H10K 59/122; H10K 59/1201; H10K 2102/351

(57) ABSTRACT

Provided are a display device, a method of manufacturing the display device, and an electronic device including the display device. The display device includes a substrate, a pixel electrode disposed on the substrate, and a pixel defining layer defining an opening exposing a central portion of the pixel electrode and including a trench portion recessed in a direction toward the pixel electrode. The pixel defining layer includes a first pixel defining layer adjacent to the opening and a second pixel defining layer spaced apart from the first pixel defining layer.

### CROSS-REFERENCE TO RELATED APPLICATION

This application is based on and claims priority under 35 U.S. C. § 119 to Korean Patent Application No. 10-2024-0153621, filed on Nov. 1, 2024, in the Korean Intellectual Property Office and Korean Patent Application No. 10-2025-0074074, filed on Jun. 5, 2025, in the Korean Intellectual Property Office, the disclosure of which is incorporated by reference herein in its entirety.

### BACKGROUND

### 1. Field

One or more embodiments relate to a display device, a method of manufacturing the display device, and an electronic device including the display device.

### 2. Description of the Related Art

As demand for display devices expands, the need for display devices for various purposes also increases. Due to such a trend, display devices tend to be manufactured larger or thinner. Therefore, there is also an increasing need for larger and thinner display devices which provide accurate and vivid colors.

### SUMMARY

One or more embodiments include a display device with improved optical characteristics, a method of manufacturing the display device, and an electronic device including the display device.

However, this is only an example, and the technical features of the disclosure are not limited thereto.

According to an aspect of the disclosure, a display device includes a substrate, a pixel electrode disposed on the substrate, and a pixel defining layer defining an opening exposing a central portion of the pixel electrode and including a trench portion recessed in a direction toward the pixel electrode. The pixel defining layer includes a first pixel defining layer adjacent to the opening and a second pixel defining layer spaced apart from the first pixel defining layer.

In some embodiments, the pixel defining layer may include a black pixel defining layer.

In some embodiments, the trench portion may be disposed to expose at least a portion of the pixel electrode.

In some embodiments, the pixel electrode may be disposed to overlap an entire area of the first pixel defining layer.

In some embodiments, the first pixel defining layer may be formed in a shape in which a width of the first pixel defining layer becomes narrower in a direction away from the pixel electrode.

In some embodiments, an inclination angle of a portion of the first pixel defining layer adjacent to the opening may be greater than an inclination angle of a portion of the first pixel defining layer adjacent to the trench portion.

In some embodiments, an inclination angle of a portion of the first pixel defining layer adjacent to the trench portion may be 11° to 45°.

In some embodiments, the pixel electrode may be disposed to overlap at least a portion of the second pixel defining layer.

In some embodiments, the first pixel defining layer and the second pixel defining layer may be spaced apart from each other by a distance of 2.0 μm to 2.2 μm.

In some embodiments, the display device may further include an anti-reflection member disposed on the pixel defining layer to overlap at least a portion of the trench portion.

According to another aspect of the disclosure, an electronic device includes a substrate, a pixel electrode disposed on the substrate, a pixel defining layer defining an opening exposing a central portion of the pixel electrode and including a trench portion recessed in a direction toward the pixel electrode, and a capping layer disposed on the trench portion.

In some embodiments, the capping layer may include a material which is different from a material of the pixel defining layer.

In some embodiments, the trench portion may be disposed to expose at least a portion of the pixel electrode.

In some embodiments, the capping layer may be disposed to cover the expose portion of the pixel electrode.

In some embodiments, the pixel defining layer may include a first pixel defining layer adjacent to the opening and a second pixel defining layer spaced apart from the first pixel defining layer.

In some embodiments, the capping layer may be disposed not to cover an uppermost end of the first pixel defining layer.

In some embodiments, the capping layer may be disposed to cover an uppermost end of the second pixel defining layer.

In some embodiments, the capping layer may overlap the first pixel defining layer by greater than 0 μm and less than or equal to 2.0 μm.

In some embodiments, a thickness from the pixel electrode to a lowermost end of the capping layer may be 0.4 μm to 0.8 μm.

In some embodiments, the display device may further include an anti-reflection member disposed on the pixel defining layer to overlap at least a portion of the trench portion.

### BRIEF DESCRIPTION OF THE DRAWINGS

These and/or other aspects will become apparent and more readily appreciated from the following description of the embodiments, taken in conjunction with the accompanying drawings.

FIG. 1 is a schematic perspective view of a display device according to an embodiment.

FIG. 2 is a cross-sectional view schematically illustrating an example of an I-I′ cross-section of FIG. 1.

FIG. 3 is a plan view schematically illustrating a portion of the display device of FIG. 1.

FIG. 4 is a circuit diagram illustrating an example of a pixel of the display device of FIG. 1.

FIG. 5 is a cross-sectional view schematically illustrating an example of a pixel of FIG. 3.

FIG. 6 is an enlarged view of region X of FIG. 5.

FIG. 7A is a photograph of a pixel defining layer according to an embodiment.

FIG. 7B is a cross-sectional view schematically illustrating an example of a IV-IV′ cross-section of FIG. 7A.

FIG. 7C is a cross-sectional view schematically illustrating an example of a V-V′ cross-section of FIG. 7A.

FIG. 8A is a diagram schematically illustrating an embodiment of a photomask used to form the pixel defining layer of FIGS. 7A to 7C.

FIG. 8B is a diagram schematically illustrating an embodiment of a photomask used to form the pixel defining layer of FIGS. 7A to 7C.

FIG. 8C is a diagram schematically illustrating the pixel defining layer formed by the photomask of FIG. 8A.

FIG. 8D is a diagram schematically illustrating the pixel defining layer formed by the photomask of FIG. 8B.

FIG. 8E is a diagram illustrating diffraction and glare in an emission area according to formation or non-formation of a trench portion and a shape of an opening by the pixel-defining layer.

FIG. 8F is a diagram illustrating a distance between adjacent trench portions according to an embodiment.

FIG. 8G is a diagram illustrating that a second pixel defining layer between adjacent trench portions in FIG. 8F has been removed.

FIG. 8H is a diagram illustrating that a second pixel defining layer does not exist between adjacent trench portions, according to an embodiment.

FIG. 8I is a diagram illustrating a trench portion and a transmission opening according to an embodiment.

FIG. 8J is a cross-sectional view illustrating an example of a VI-VI′ cross-section of FIG. 8I.

FIG. 8K is a diagram illustrating that a second pixel defining layer between the trench portion and the transmission opening in FIG. 8I has been removed.

FIG. 8L is a diagram illustrating that a second pixel defining layer does not exist between a transmission opening and a trench portion, according to an embodiment.

FIG. 8M is a diagram illustrating that the second pixel defining layer adjacent to the transmission opening in FIG. 8L has been removed.

FIG. 8N is another diagram illustrating that the second pixel defining layer adjacent to the transmission opening in FIG. 8L has been removed.

FIG. 9 is a diagram for describing a process of forming the pixel defining layer of FIGS. 7A to 7C.

FIG. 10A is a diagram for describing a pixel defining layer on which a capping layer is formed, according to an embodiment.

FIG. 10B is another diagram for describing a pixel defining layer on which a capping layer is formed, according to an embodiment.

FIG. 10C is a diagram schematically illustrating an embodiment of a photomask used to form the capping layer of FIG. 10A or 10B.

FIG. 10D is a diagram for describing a process of forming the capping layer of FIG. 10A or 10B and of a III-III″ cross-section of FIG. 10C.

FIG. 11A is a diagram for describing a pixel defining layer on which a separator is formed, according to an embodiment.

FIG. 11B is a schematic diagram illustrating a process of forming a separator in a pixel defining layer, according to an embodiment.

FIG. 11C is a photograph of the separator formed in the pixel defining layer, according to an embodiment.

FIG. 12 is a diagram for describing a reflection path of light in a display device according to the disclosure.

FIGS. 13A and 13B are photographs for describing an effect of improving optical characteristics in the display device of FIG. 12.

FIG. 14A is a diagram illustrating an embodiment of a display device, from which an anti-reflection member has been removed, according to the disclosure.

FIG. 14B is a diagram illustrating an embodiment of a display device, from which an anti-reflection member has been removed, according to the disclosure.

FIG. 14C is a diagram illustrating an embodiment of a display device, from which an anti-reflection member has been removed, according to the disclosure.

FIGS. 15 and 16 are tables for describing an effect of improving optical characteristics according to the thickness of the capping layer.

FIG. 17 is a flowchart of a method of manufacturing a display device, according to an embodiment.

FIG. 18 is a block diagram schematically illustrating an example of an electronic device according to embodiments.

### DETAILED DESCRIPTION

As the present description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

In the following embodiments, the terms “first,” “second,” etc. are not used in a restrictive sense and are used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

In the following embodiments, it will be understood that, when a portion such as unit, region, or element is referred to as being “on” another portion, this may include not only a case where the portion is directly on the other portion, but also a case where intervening units, regions, or elements may be present therebetween.

In the following embodiments, it will be understood that the terms “connection” or “coupling” do not necessarily mean “direct and/or fixed connection or coupling” of two members, unless the context clearly indicates otherwise, and this does not preclude the disposition of other members between the two members.

Additionally, the term “about” is intended to account for variations due to experimental error or manufacturing tolerances and should be interpreted as encompassing values that achieve substantially the same result.

Also, sizes of elements in the drawings may be exaggerated or reduced for convenience of explanation. For example, because sizes and/or thicknesses of elements in the drawings are arbitrarily illustrated for convenience of explanation, the disclosure is not limited thereto.

Hereinafter, embodiments will be described in detail with reference to the accompanying drawings. When describing embodiments with reference to the accompanying drawings, the same or corresponding elements are denoted by the same reference numerals, and redundant descriptions thereof are omitted.

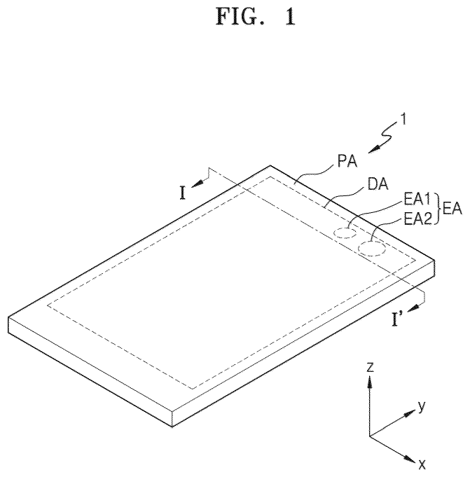

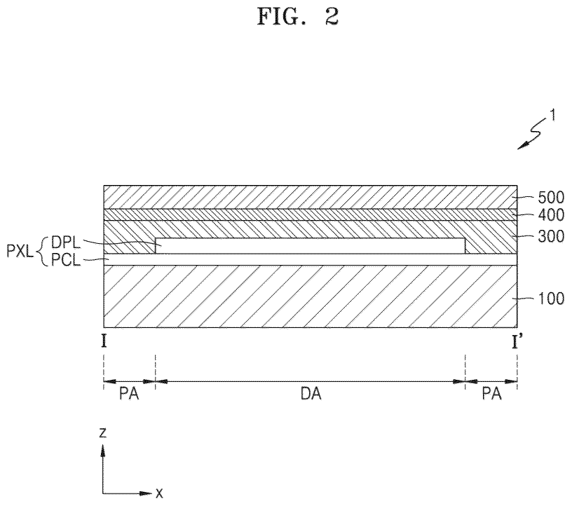

FIG. 1 is a schematic perspective view of a display device 1 according to an embodiment and FIG. 2 is a cross-sectional view schematically illustrating an example of an I-I′ cross-section of FIG. 1.

Referring to FIG. 1, the display device 1 according to an embodiment may include a display area DA and a peripheral area PA. The peripheral area PA may be disposed outside the display area DA to surround the display area DA. Various wirings and driving circuits configured to transmit electrical signals to be applied to the display area DA may be disposed in the peripheral area PA. The display device 1 may provide an image by using light emitted from a plurality of pixels disposed in the display area DA. Although not illustrated, the display device 1 may include a bending area in a portion of the peripheral area PA so that the display device 1 is bendable in the bending area.

Examples of the display device 1 may include an organic light-emitting display, an inorganic light-emitting display (or an inorganic electroluminescence (EL) display), a quantum dot light-emitting display, and the like. Hereinafter, an organic light-emitting display is described as an example of the display device 1. The display device 1 may be implemented as various types of electronic devices, such as a mobile phone, a laptop, or a smart watch.

As illustrated in FIG. 2, the display device 1 may include a substrate 100, a pixel layer PXL on the substrate 100, an encapsulation member 300 which seals the pixel layer PXL, a touch sensing layer 400 on the encapsulation member 300, and a cover layer 500 on the touch sensing layer 400, which are stacked in a thickness direction (a z direction).

The substrate 100 may include glass or polymer resin. For example, the substrate 100 may include a glass material including SiO₂ as a main component, or may include other flexible or bendable materials, for example, resin, such as reinforced plastic. Although not illustrated, the substrate 100 may include a bending area in a portion of the peripheral area PA so that the substrate 100 is bendable therein.

The pixel layer PXL may be disposed on the substrate 100. The pixel layer PXL may include a display element layer DPL including display elements disposed for each pixel and a pixel circuit layer PCL including a pixel circuit and insulating layers disposed for each pixel. The display element layer DPL may be disposed on the pixel circuit layer PCL, and a plurality of insulating layers may be disposed between the pixel circuit and the display element. Some lines and insulating layers of the pixel circuit layer PCL may extend up to the peripheral area PA.

The encapsulation member 300 may be a thin-film encapsulation layer. The thin-film encapsulation layer may include at least one inorganic encapsulation layer and at least one organic encapsulation layer. In case that the display device 1 includes the substrate 100 including polymer resin and the encapsulation member 300 which is the thin-film encapsulation layer including an inorganic encapsulation layer and an organic encapsulation layer, the flexibility of the display device 1 may be improved.

The touch sensing layer 400 may be configured to obtain coordinate information according to external input, for example, a touch event.

The touch sensing layer 400 may include a sensing electrode (or a touch electrode) and trace lines connected to the sensing electrode. The touch sensing layer 400 may be configured to sense external input by using a mutual capacitance method and/or a self-capacitance method.

In an embodiment, the touch sensing layer 400 may be a capacitive touch sensing layer. In case that the cover layer 500 is touched, a change in capacitance occurs between the sensing electrode of the touch sensing layer 400 and an opposite electrode. The touch sensing layer 400 may sense the change in capacitance and may determine the contact or non-contact of the corresponding portion.

The touch sensing layer 400 may be formed directly on a display panel. For example, the touch sensing layer 400 may be formed separately and then bonded through an adhesive layer, such as an optical clear adhesive (OCA). For example, the touch sensing layer 400 may be continuously formed after the process of forming the display panel. In this case, an adhesive layer may not be disposed between the touch sensing layer 400 and the display panel.

The cover layer 500 may be disposed on the touch sensing layer 400 to protect the display device 1.

The cover layer 500 may be flexible. The cover layer 500 may include polymethyl methacrylate, polydimethylsiloxane, polyimide, acrylate, polyethylene terephthalate, polyethylene naphthalate, or the like. However, the disclosure is not limited thereto and the cover layer 500 may include other materials, such as metal. In some cases, the cover layer 500 may include a thin metal foil, such as steel use stainless (SUS).

In some embodiments, paying particular attention to FIG. 1, a display panel DP may include a component area EA. Specifically, the display panel DP may include a first component area EA1 and a second component area EA2. The first component area EA1 and the second component area EA2 may be at least partially surrounded by the display area DA. The first component area EA1 and the second component area EA2 are illustrated as being spaced apart from each other, but the disclosure is not limited thereto, and the first component area EA1 and the second component area EA2 may be at least partially connected to each other. The first component area EA1 and the second component area EA2 may be areas where components using infrared light, visible light, sound, or the like are disposed therebelow.

An optical element may be disposed below the display panel DP. The optical element may include a first optical element overlapping the first component area EA1 and a second optical element overlapping the second component area EA2. In this case, the optical element corresponding to the first component area EA1 may be a light sensor, and the optical element corresponding to the second component area EA2 may be a camera.

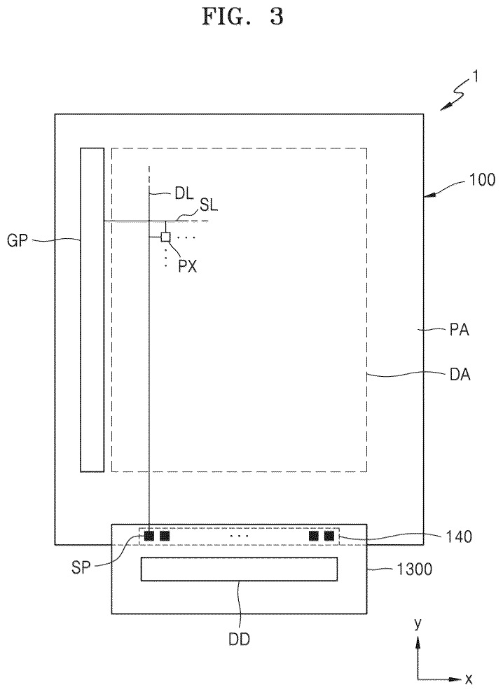

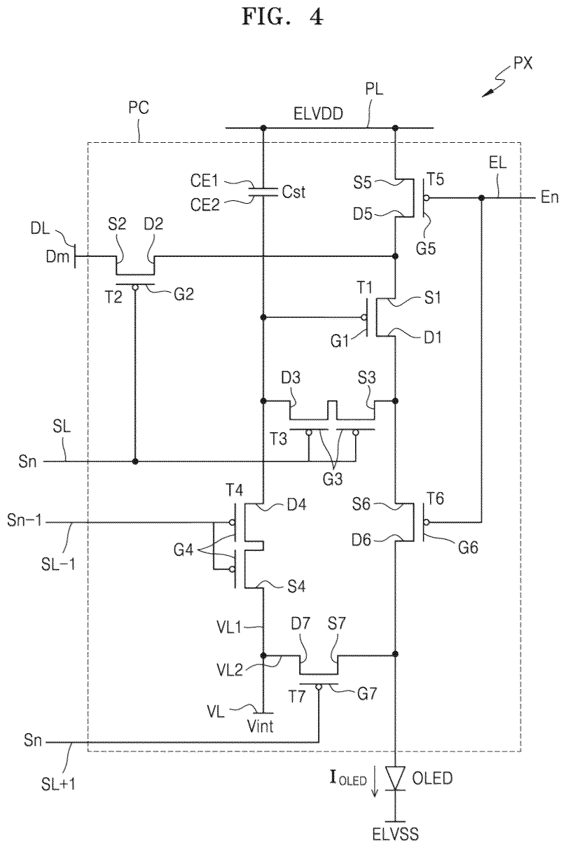

FIG. 3 is a plan view schematically illustrating a portion of the display device 1 of FIG. 1 and FIG. 4 is a circuit diagram illustrating an example of a pixel of the display device 1 of FIG. 1.

Referring to FIG. 3, a substrate 100 may include a display area DA and a peripheral area PA. The peripheral area PA may be disposed outside the display area DA to surround the display area DA.

A plurality of pixels PX may be disposed in the display area DA of the substrate 100 in a pattern in a first direction (an x direction or a row direction) and a second direction (a y direction or a column direction).

A scan driver GP configured to provide a scan signal to each of the pixels PX, a data driver DD configured to provide a data signal to each of the pixels PX, and main power lines (not shown) configured to provide a first power supply voltage (see ELVDD of FIG. 4) and a second power supply voltage (see ELVSS of FIG. 4) may be disposed in the peripheral area PA of the substrate 100. A pad portion 140 in which a plurality of signal pads SP respectively connected to data lines DL are disposed may be disposed in the peripheral area PA of the substrate 100.

The scan driver GP may include an oxide semiconductor thin-film transistor (TFT) gate driver circuit (OSG) or an amorphous silicon TFT gate driver circuit (ASG). FIG. 3 illustrates that the scan driver GP is disposed adjacent to a side of the substrate 100, but in an embodiment, the scan drivers GP may be respectively disposed adjacent to two opposite sides of the substrate 100.

FIG. 3 illustrates a chip on film (COF) method in which the data driver DD is disposed on a film 1300 electrically connected to the signal pads SP on the substrate 100. According to an embodiment, the data driver DD may be disposed directly on the substrate 100 in a chip on glass (COG) or chip on plastic (COP) method. The data driver DD may be electrically connected to a flexible printed circuit board (FPCB).

Referring to FIG. 4, a pixel PX may include a pixel circuit PC and an organic light-emitting diode OLED electrically connected to the pixel circuit PC.

The pixel PX may emit, for example, red light, green light, blue light, or white light through the organic light-emitting diode OLED.

The pixel circuit PC may include a plurality of transistors T1 to T7 and a storage capacitor Cst, as illustrated in FIG. 4. The transistors T1 to T7 and the storage capacitor Cst may be connected to signal lines SL, SL−1, SL+1, EL, and DL, a first initialization voltage line VL1, a second initialization voltage line VL2, and a driving voltage line PL.

The signal lines SL, SL−1, SL+1, EL, and DL may include a scan line SL configured to transmit a scan signal Sn, a previous scan line SL−1 configured to transmit a previous scan signal Sn−1 to a first initialization transistor T4, a next scan line SL+1 configured to transmit the scan signal Sn to a second initialization transistor T7, an emission control line EL configured to transmit an emission control signal En to an operation control transistor T5 and an emission control transistor T6, and a data line DL crossing the scan line SL and configured to transmit a data signal Dm. The driving voltage line PL may be configured to transmit a driving voltage ELVDD to a driving transistor T1, the first initialization voltage line VL1 may be configured to transmit an initialization voltage Vint to the first initialization transistor T4, and the second initialization voltage line VL2 may be configured to transmit the initialization voltage Vint to the second initialization transistor T7. The first initialization voltage line VL1 and the second initialization voltage line VL1 may be collectively referred to as an initialization voltage line VL.

A driving gate electrode G1 of the driving transistor T1 may be connected to a lower electrode CE1 of the storage capacitor Cst, a driving source electrode S1 of the driving transistor T1 may be connected to the driving voltage line PL via the operation control transistor T5, and a driving drain electrode D1 of the driving transistor T1 may be electrically connected to a pixel electrode of the organic light-emitting diode OLED via the emission control transistor T6. The driving transistor T1 may be configured to receive the data signal Dm according to the switching operation of the switching transistor T2 and supply a driving current I_{OLED} to the organic light-emitting diode OLED.

A switching gate electrode G2 of the switching transistor T2 may be connected to the scan line SL, a switching source electrode S2 of the switching transistor T2 may be connected to the data line DL, and a switching drain electrode D2 of the switching transistor T2 may be connected to the driving source electrode S1 of the driving transistor T1 and connected to the driving voltage line PL via the operation control transistor T5. The switching transistor T2 may be configured to be turned on in response to the scan signal Sn received through the scan line SL and perform a switching operation to transmit the data signal Dm received from the data line DL to the driving source electrode S1 of the driving transistor T1.

A compensation gate electrode G3 of a compensation transistor T3 may be connected to the scan line SL, a compensation source electrode S3 of the compensation transistor T3 may be connected to the driving drain electrode D1 of the driving transistor T1 and connected to the pixel electrode of the organic light-emitting diode OLED via the emission control transistor T6, and a compensation drain electrode D3 of the compensation transistor T3 may be connected to the lower electrode CE1 of the storage capacitor Cst, a first initialization drain electrode D4 of the first initialization transistor T4, and the driving gate electrode G1 of the driving transistor T1. The compensation transistor T3 may be configured to be turned on in response to the scan signal Sn received through the scan line SL and electrically connect the driving gate electrode G1 of the driving transistor T1 to the driving drain electrode D1 of the driving transistor T1 so that the driving transistor T1 may be diode-connected.

A first initialization gate electrode G4 of the first initialization transistor T4 may be connected to the previous scan line SL−1, a first initialization source electrode S4 of the first initialization transistor T4 may be connected to the first initialization voltage line VL1, and the first initialization drain electrode D4 of the first initialization transistor T4 may be connected to the lower electrode CE1 of the storage capacitor Cst, the compensation drain electrode D3 of the compensation transistor T3, and the driving gate electrode G1 of the driving transistor T1. The first initialization transistor T4 may be configured to be turned on in response to the previous scan signal Sn-1 received through the previous scan line SL−1 and perform an initialization operation to transmit the initialization voltage Vint to the driving gate electrode G1 of the driving transistor T1 so as to initialize the voltage of the driving gate electrode G1 of the driving transistor T1.

An operation control gate electrode G5 of the operation control transistor T5 may be connected to the emission control line EL, an operation control source electrode S5 of the operation control transistor T5 may be connected to the driving voltage line PL, and an operation control drain electrode D5 of the operation control transistor T5 may be connected to the driving source electrode S1 of the driving transistor T1 and the switching drain electrode D2 of the switching transistor T2.

An emission control gate electrode G6 of the emission control transistor T6 may be connected to the emission control line EL, an emission control source electrode S6 of the emission control transistor T6 may be connected to the driving drain electrode D1 of the driving transistor T1 and the compensation source electrode S3 of the compensation transistor T3, and an emission control drain electrode D6 of the emission control transistor T6 may be electrically connected to a second initialization source electrode S7 of the second initialization transistor T7 and the pixel electrode of the organic light-emitting diode OLED.

The operation control transistor T5 and the emission control transistor T6 may be configured to be simultaneously turned on in response to the emission control signal En received through the emission control line EL and transmit the driving voltage ELVDD to the organic light-emitting diode OLED so that the driving current I_{OLED} flows through the organic light-emitting diode OLED.

A second initialization gate electrode G7 of the second initialization transistor T7 may be connected to the next scan line SL+1, the second initialization source electrode S7 of the second initialization transistor T7 may be connected to the emission control drain electrode D6 of the emission control transistor T6 and the pixel electrode of the organic light-emitting diode OLED, and a second initialization drain electrode D7 of the second initialization transistor T7 may be connected to the second initialization voltage line VL2.

Because the scan line SL and the next scan line SL+1 are electrically connected to each other, the same scan signal Sn may be applied to the scan line SL and the next scan line SL+1. Accordingly, the second initialization transistor T7 may be configured to be turned on in response to the scan signal Sn received through the next scan line SL+1 and perform an initialization operation to initialize the pixel electrode of the organic light-emitting diode OLED.

An upper electrode CE2 of the storage capacitor Cst may be connected to the driving voltage line PL and a common electrode of the organic light-emitting diode OLED may be connected to a common voltage ELVSS. Accordingly, the organic light-emitting diode OLED may be configured to receive the driving current I_{OLED} from the driving transistor T1 and emit light to display an image.

Although FIG. 4 illustrates that each of the compensation transistor T3 and the first initialization transistor T4 has dual gate electrodes, each of the compensation transistor T3 and the first initialization transistor T4 may have a single gate electrode.

Although the structure of the single pixel circuit PC has been described with reference to FIG. 4, a plurality of pixels PX having the same pixel circuit PC may be disposed to form a plurality of rows. At this time, the first initialization voltage line VL1, the previous scan line SL−1, the second initialization voltage line VL2, and the next scan line SL+1 may be shared by neighboring pixels.

For example, the first initialization voltage line VL1 and the previous scan line SL−1 may be electrically connected to a second initialization transistor of another pixel circuit PC disposed along the second direction (the y direction). Accordingly, the previous scan signal applied to the previous scan line SL−1 may be transmitted to the second initialization transistor of the other pixel circuit PC as a next scan signal. Similarly, the second initialization voltage line VL2 and the next scan line SL+1 may be electrically connected to a first initialization transistor of another pixel circuit PC disposed adjacent thereto along the second direction (the y direction) with respect to the drawing and configured to transmit the previous scan signal and the initialization voltage to the first initialization transistor of the other pixel circuit PC.

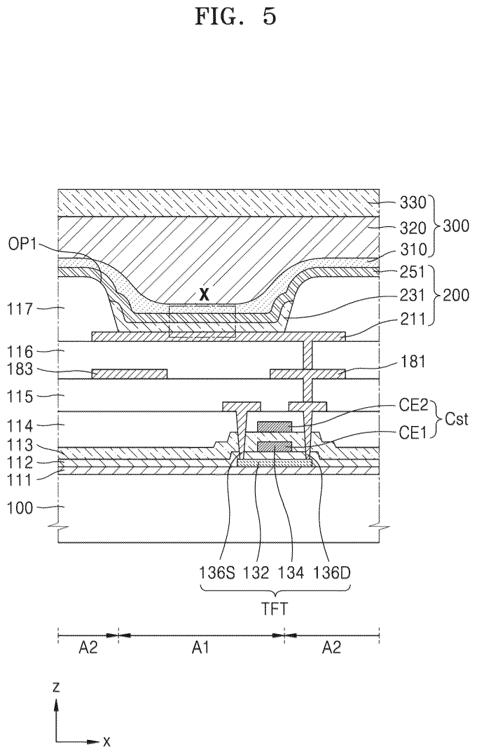

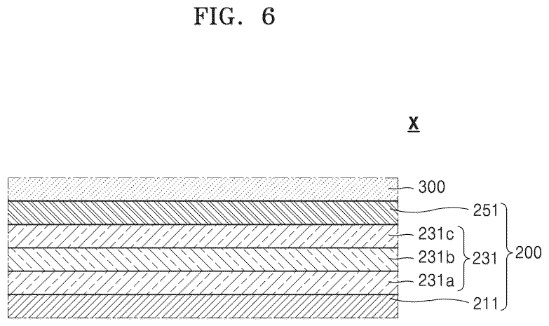

FIG. 5 is a cross-sectional view schematically illustrating an example of the cross-section of the pixel of FIG. 3 and FIG. 6 is an enlarged view of region X of FIG. 5.

Referring to FIGS. 5 and 6, a buffer layer 111 may be disposed on a substrate 100 so as to prevent infiltration of impurities into a semiconductor layer of a thin-film transistor.

The substrate 100 may include various materials, such as glass, metal, or plastic. In an embodiment, the substrate 100 may be a flexible substrate. For example, the substrate 100 may include polymer resin, such as polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate, or cellulose acetate propionate (CAP).

The buffer layer 111 may include an inorganic insulating material, such as silicon nitride or silicon oxide, and may be a single layer or layers.

A thin-film transistor TFT, a capacitor Cst, and an organic light-emitting diode 200 electrically connected to the thin-film transistor TFT may be disposed on the substrate 100. The expression “the organic light-emitting diode 200 is electrically connected to the thin-film transistor TFT” may mean that a pixel electrode 211 is electrically connected to the thin-film transistor TFT. The thin-film transistor TFT may be the first transistor T1 of FIG. 4.

The thin-film transistor TFT may include a semiconductor layer 132, a gate electrode 134, a source electrode 136S, and a drain electrode 136D. The semiconductor layer 132 may include an oxide semiconductor material. The semiconductor layer 132 may include amorphous silicon, polycrystalline silicon, or an organic semiconductor material. The gate electrode 134 may include a single layer or layers including one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), taking into account adhesion to adjacent layers, surface flatness of the stacked layers, and processability.

A gate insulating layer 112 including an inorganic material, such as silicon oxide, silicon nitride, and/or silicon oxynitride, may be disposed between the semiconductor layer 132 and the gate electrode 134. A first interlayer insulating layer 113 and a second interlayer insulating layer 114 each including an inorganic material, such as silicon oxide, silicon nitride, and/or silicon oxynitride, may be disposed between the gate electrode 134 and the source electrode 136S and between the gate electrode 134 and the drain electrode 136D. The source electrode 136S and the drain electrode 136D may be electrically connected to the semiconductor layer 132 through contact holes formed in the gate insulating layer 112, the first interlayer insulating layer 113, and the second interlayer insulating layer 114.

The source electrode 136S and the drain electrode 136D may each include a single layer or layers including one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu).

The capacitor Cst may include a lower electrode CE1 and an upper electrode CE2 which overlap each other with the first interlayer insulating layer 113. The first interlayer insulating layer 113 may be disposed between the lower electrode CE1 and the upper electrode CE2. The capacitor Cst may overlap the thin-film transistor TFT. FIG. 5 illustrates that the gate electrode 134 of the thin-film transistor TFT is the lower electrode CE1 of the capacitor Cst. In an embodiment, the capacitor Cst may not overlap the thin-film transistor TFT. The capacitor Cst may be covered by the second interlayer insulating layer 114.

A pixel circuit including the thin-film transistor TFT and the capacitor Cst may be covered by a first insulating layer 115 and a second insulating layer 116. The first insulating layer 115 and the second insulating layer 116 may each be an organic insulating layer which is a planarization insulating layer. The first insulating layer 115 and the second insulating layer 116 may each include an organic insulating material, for example, general-purpose polymer such as polymethylmethacrylate (PMMA) or polystyrene (PS), polymer derivatives having a phenolic group, acrylic-based polymer, imide-based polymer, aryl ether-based polymer, amide-based polymer, fluorine-based polymer, p-xylene-based polymer, vinyl alcohol-based polymer, and any blend thereof. In an embodiment, the first insulating layer 115 and the second insulating layer 116 may each include polyimide (PI).

A display element, for example, the organic light-emitting diode 200 may be disposed on the second insulating layer 116. The organic light-emitting diode 200 may include the pixel electrode 211, an intermediate layer 231, and an opposite electrode 251.

The pixel electrode 211 may be disposed on the second insulating layer 116 and may be connected to the thin-film transistor TFT through a connection electrode 181 on the first insulating layer 115. Wirings 183, such as a data line DL and a driving voltage line PL, may be disposed on the first insulating layer 115.

The pixel electrode 211 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 211 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. In an embodiment, the pixel electrode 211 may further include a layer including ITO, IZO, ZnO, or In₂O₃ above and/or below the reflective layer.

A third insulating layer 117 may be disposed on the second insulating layer 116. The third insulating layer 117 may be a pixel defining layer which covers the edge of the pixel electrode 211 and defines a pixel by having an opening OP1 which extends to and exposes a portion of the pixel electrode 211. The opening OP1 may correspond to a first area A1. The area other than the opening OP1 may correspond to a second area A2. The third insulating layer 117 may prevent an electric arc or the like from occurring on the edge of the pixel electrode 211 by increasing the distance between the edge of the pixel electrode 211 and the opposite electrode 251. The third insulating layer 117 may include, for example, an organic material, such as PI or hexamethyldisiloxane (HMDSO).

The intermediate layer 231 may include an emission layer 231b. The emission layer 231b may include a high molecular weight organic material or a low molecular weight organic material which emits light of a selected color. In an embodiment, the intermediate layer 231 may include a first functional layer 231a disposed below the emission layer 231b and/or a second functional layer 231c disposed above the emission layer 231b. The first functional layer 231a and/or the second functional layer 231c may include a layer which is integral across the plurality of pixel electrodes 211, or may include layers patterned to respectively correspond to the plurality of pixel electrodes 211.

The first functional layer 231a may be a single layer or layers. For example, in case that the first functional layer 231a includes a high molecular weight material, the first functional layer 231a may be a single-layered hole transport layer (HTL) and may include polyethylene dihydroxythiophene (PEDOT: poly-(3,4)-ethylene-dihydroxy thiophene) or polyaniline (PANI). In case that the first functional layer 231a includes a low molecular weight material, the first functional layer 231a may include a hole injection layer (HIL) and an HTL.

The second functional layer 231c may be omitted. For example, in case that the first functional layer 231a and the emission layer 231b each include a high molecular weight material, the second functional layer 231c may be formed to improve characteristics of the organic light-emitting diode 200. The second functional layer 231c may be a single layer or layers. The second functional layer 231c may include an electron transport layer (ETL) and/or an electron injection layer (EIL).

Although not illustrated, a spacer may be further formed on the third insulating layer 117. The spacer may include an organic insulating material, such as PI. For example, the spacer may include an inorganic insulating material, such as silicon nitride or silicon oxide, or may include an organic insulating material and an inorganic insulating material.

The spacer may include a material which is different from a material of the third insulating layer 117. In other embodiments, the spacer may include a same material as a material of the third insulating layer 117. In an embodiment, the third insulating layer 117 and the spacer may each include PI.

The opposite electrode 251 may be disposed to face the pixel electrode 211 with the intermediate layer 231. The intermediate layer 231 may be disposed between the opposite electrode 251 and the pixel electrode 211. The opposite electrode 251 may include a conductive material having a low work function. For example, the opposite electrode 251 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. In other embodiments, the opposite electrode 251 may further include a layer including ITO, IZO, ZnO, or In₂O₃ on the (semi)transparent layer including the material described above.

The opposite electrode 251 may be disposed on the intermediate layer 231 and the third insulating layer 117. The opposite electrode 251 may be formed integrally with a plurality of organic light-emitting diodes 200 in the display area DA and may be opposite the plurality of pixel electrodes 211.

A thin-film encapsulation layer may be disposed on the opposite electrode 251 as an encapsulation member 300. The thin-film encapsulation layer may protect the organic light-emitting diode 200 from ambient moisture or oxygen. The thin-film encapsulation layer may have a multilayer structure. The thin-film encapsulation layer may include a first inorganic layer 310, an organic layer 320, and a second inorganic layer 330. By forming the thin-film encapsulation layer in a multilayer structure, even when cracks occur in the thin-film encapsulation layer, such cracks may be prevented from being connected to each other between the inorganic layer and the organic layer. This may prevent or minimize the formation of a path through which ambient moisture or oxygen penetrates into the display area. In an embodiment, the number of organic layers, the number of inorganic layers, and the stacking order of the organic layers and the inorganic layers may be changed.

For example, the first inorganic layer 310 may cover the opposite electrode 251 and may include at least one inorganic insulating material selected from aluminum oxide, titanium oxide, tantalum oxide, hafnium oxide, zinc oxide, silicon oxide, silicon nitride, and silicon oxynitride. Because the first inorganic layer 310 is formed along the structure below the first inorganic layer 310, the upper surface of the first inorganic layer 310 may not be flat.

The organic layer 320 may cover the first inorganic layer 310 and may have a sufficient thickness. The upper surface of the organic layer 320 may be substantially flat across the entire display area. The organic layer 320 may include polyethylene terephthalate, polyethylene naphthalate, polycarbonate, polyimide, polyethylene sulfonate, polyoxymethylene, polyarylate, hexamethyldisiloxane, acrylic resin (e.g., polymethylmethacrylate or polyacrylic acid), or any combination thereof.

The second inorganic layer 330 may cover the organic layer 320 and may include at least one inorganic insulating material selected from aluminum oxide, titanium oxide, tantalum oxide, hafnium oxide, zinc oxide, silicon oxide, silicon nitride, and silicon oxynitride. The second inorganic layer 330 may extend outside the organic layer and may come into contact with the first inorganic layer 310 in the peripheral area so that the organic layer is not exposed to the outside.

In the process of forming the thin-film encapsulation layer, the structures below the thin-film encapsulation layer may be damaged. For example, in case that the first inorganic layer 310 is formed, the immediately underlying layer on which the first inorganic layer 310 is formed may be damaged. Therefore, to prevent damage to the underlying structure in the process of forming the thin-film encapsulation layer, at least one capping layer and/or protective layer may be disposed between the opposite electrode 251 and the thin-film encapsulation layer. The protective layer may include an inorganic material.

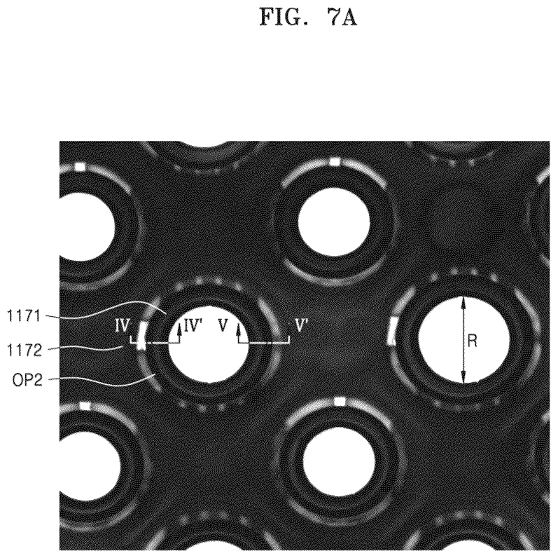

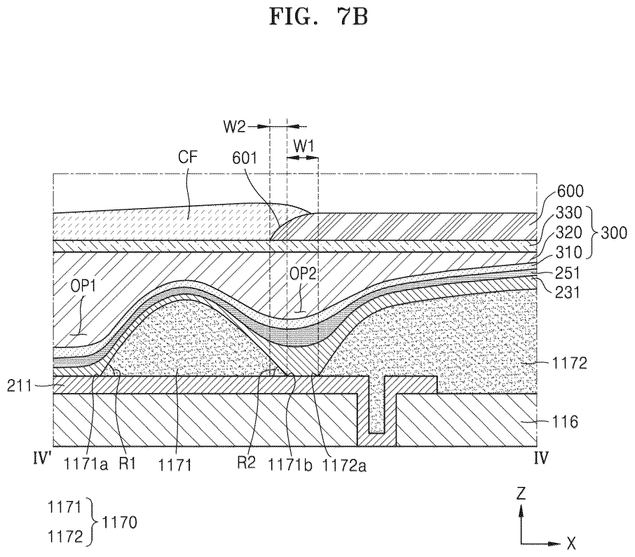

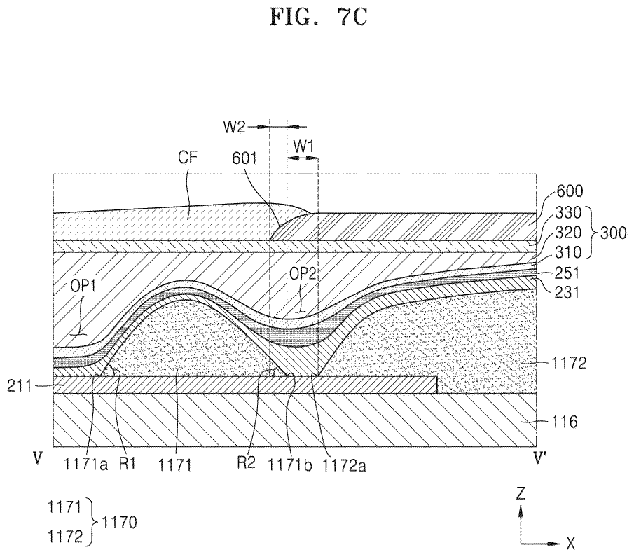

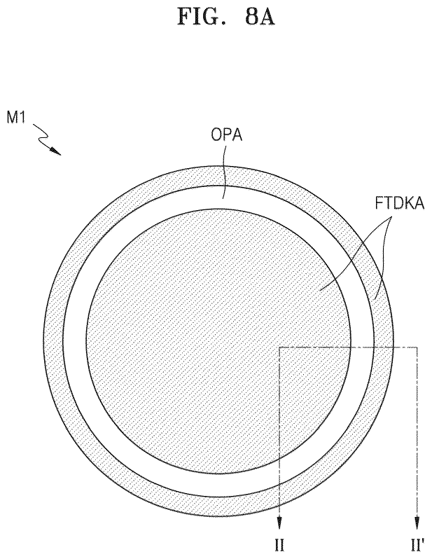

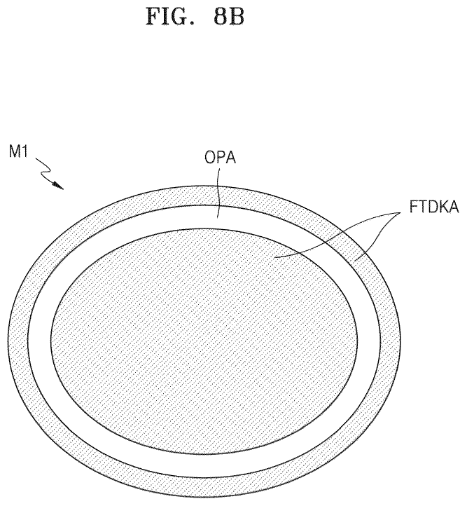

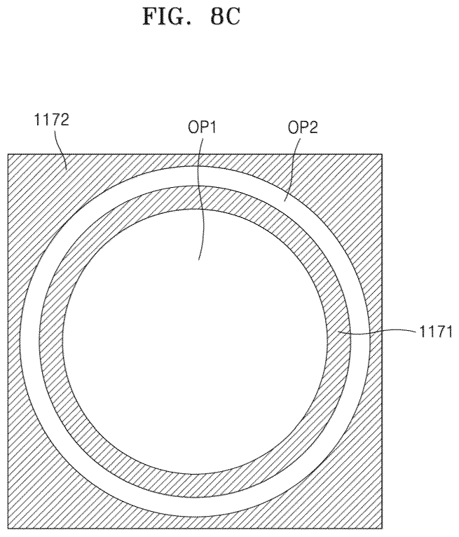

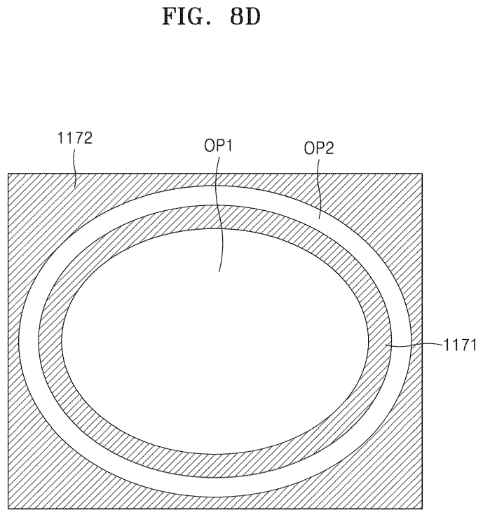

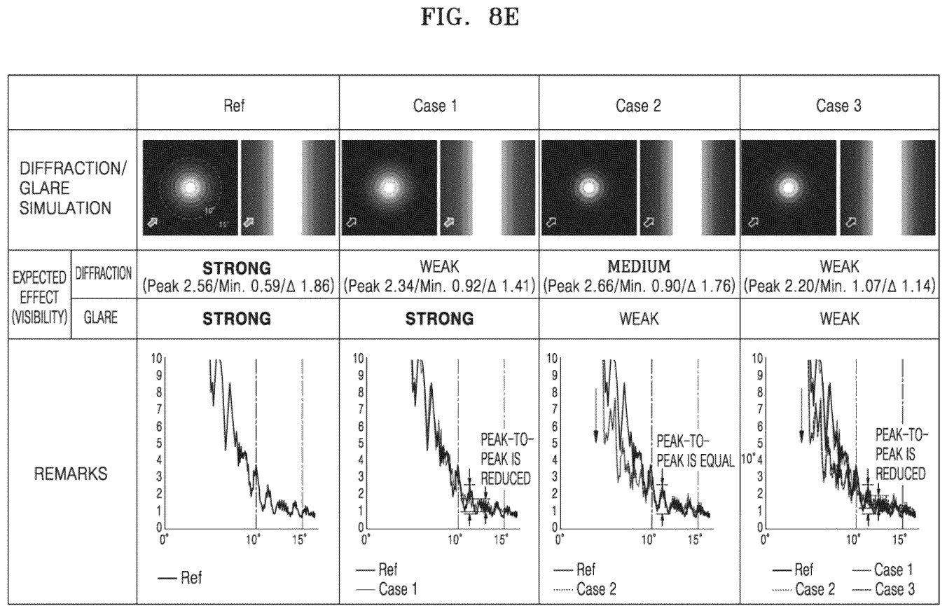

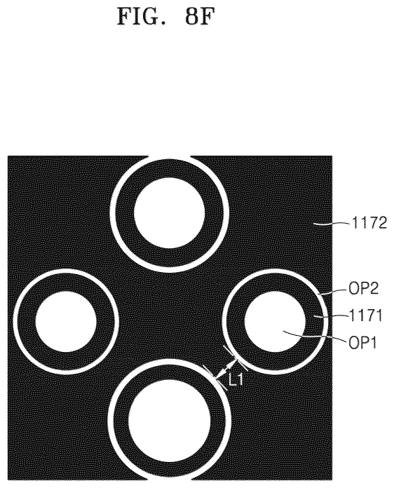

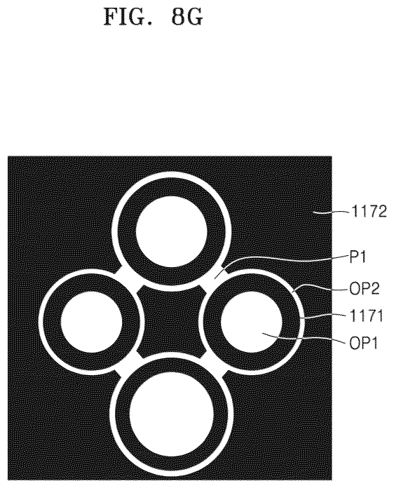

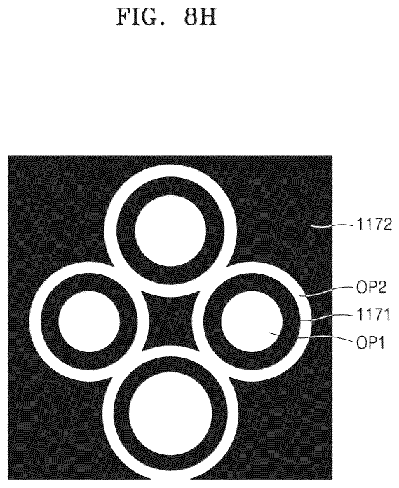

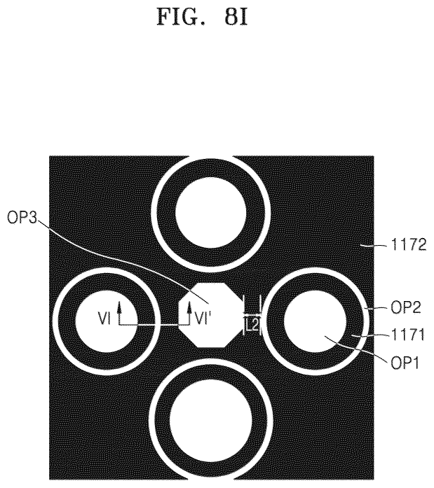

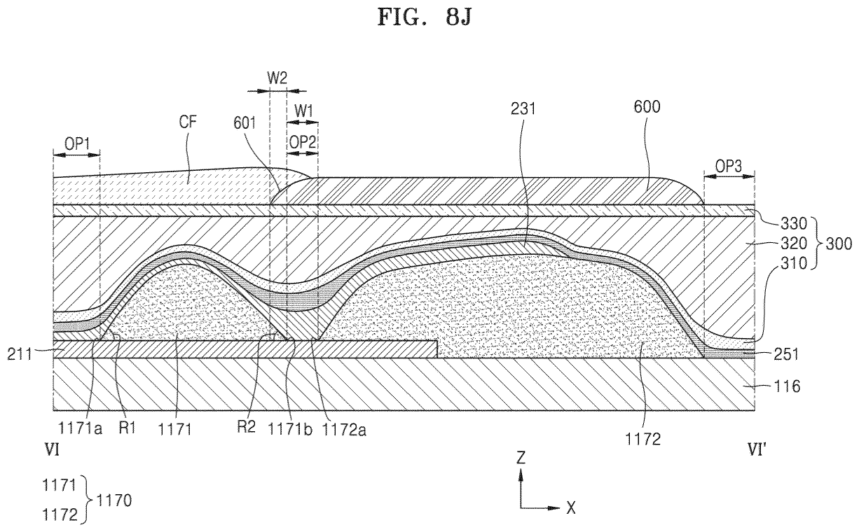

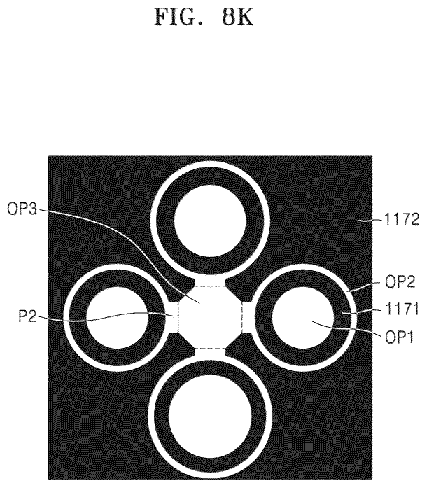

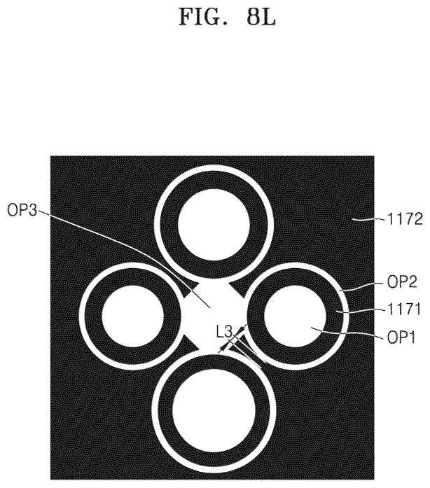

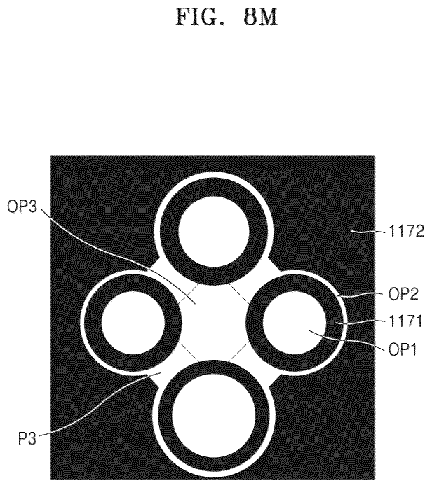

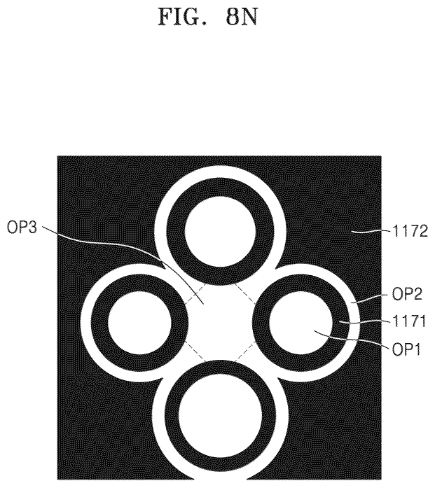

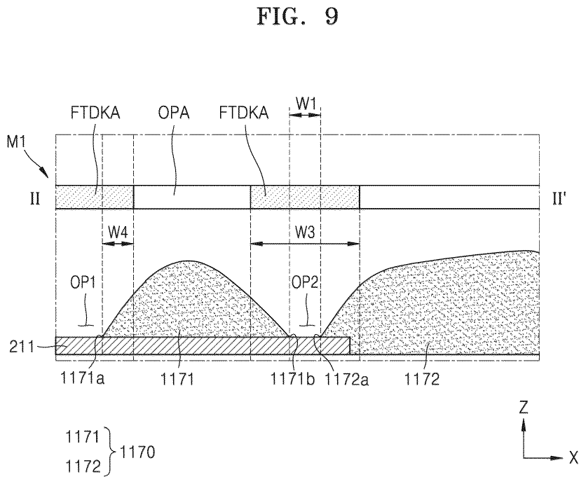

FIG. 7A is a photograph of a top view of a pixel defining layer according to an embodiment. FIG. 7B is a cross-sectional view schematically illustrating an example of a IV-IV′ cross-section of FIG. 7A. FIG. 7C is a cross-sectional view schematically illustrating an example of a V-V′ cross-section of FIG. 7A. FIG. 8A is a diagram schematically illustrating an embodiment of a photomask used to form the pixel defining layer of FIGS. 7A to 7C. FIG. 8B is a diagram schematically illustrating an embodiment of a photomask used to form the pixel defining layer of FIGS. 7A to 7C. FIG. 8C is a diagram schematically illustrating the pixel defining layer formed by the photomask of FIG. 8A. FIG. 8D is a diagram schematically illustrating the pixel defining layer formed by the photomask of FIG. 8B. FIG. 8E is a diagram illustrating diffraction and glare in an emission area according to formation or non-formation of a trench portion and a shape of an opening by the pixel-defining layer. FIG. 9 is a diagram for describing a process of forming the pixel defining layer of FIGS. 7A to 7C.

Hereinafter, for convenience of explanation, contents which are the same as provided above or may be easily applied by those of ordinary skill in the art are omitted or briefly described.

Referring to FIGS. 7A to 9, a display device 1 according to an embodiment may include a substrate 100, a pixel electrode 211 disposed on the substrate 100, a pixel defining layer 1170, of which at least a portion overlaps the pixel electrode 211, an intermediate layer 231 disposed on the pixel electrode 211, and an opposite electrode 251 disposed on the intermediate layer 231.

The pixel electrode 211 may be disposed on the substrate 100. For example, the pixel electrode 211 may be formed on the substrate 100. As described above, a plurality of layers may be further formed between the pixel electrode 211 and the substrate 100.

The pixel defining layer 1170 may be disposed on the substrate 100. The pixel defining layer 1170 may be all or part of the third insulating layer 117.

At least a portion of the pixel defining layer 1170 may be disposed to overlap the pixel electrode 211. The pixel defining layer 1170 may be disposed to extend to and expose the central portion of the pixel electrode 211. For example, the pixel defining layer 1170 may be disposed to cover the edge of the pixel electrode 211 so as to include an opening OP1 which extends to and exposes the central portion of the pixel electrode 211. For example, the pixel defining layer 1170 may be formed to define the opening OP1. The opening OP1 defined by the pixel defining layer 1170 may have a circular shape, and a diameter R of the circular shape of the opening OP1 may be about 10 μm to about 30 μm, but the disclosure is not limited thereto.

The intermediate layer 231 may be disposed on the pixel electrode 211. For example, at least a portion of the intermediate layer 231 may overlap the opening OP1.

The opposite electrode 251 may be disposed on the intermediate layer 231. For example, the opposite electrode 251 may be disposed to face the pixel electrode 211 with the intermediate layer 231. The intermediate layer 231 may be disposed between the opposite electrode 251 and the pixel electrode 211.

The opposite electrode 251 may be disposed on the intermediate layer 231 and the pixel defining layer 1170. For example, the opposite electrode 251 may be formed to cover the intermediate layer 231 and the pixel defining layer 1170.

In an embodiment, the pixel defining layer 1170 may be a black pixel defining layer 1170. For example, the pixel defining layer 1170 may include a light-absorbing material, or may include black pigment or black dye. The pixel defining layer 1170 which includes black pigment or black dye may implement the black pixel defining layer 1170. In case that the pixel defining layer 1170 is formed, carbon black or the like may be used as the black pigment or black dye, but the disclosure is not limited thereto.

The pixel defining layer 1170 may be implemented as the black pixel defining layer 1170 and may absorb at least a portion of light incident on the pixel defining layer 1170. The light may be external light or reflected light reflected from the opposite electrode 251.

In this case, a polarizing plate may not be formed on the front surface of the display panel DP according to an embodiment. Instead, the pixel defining layer 1170 may be formed of a black organic material, and an anti-reflection member 600 and a color filter CF may be formed above the pixel defining layer 1170. Accordingly, even when external light is incident inside the display panel DP, the external light may be reflected from an anode or the like, and thus, the external light may not be transmitted to a user. In some embodiments, because a polarizing plate is not formed, the light emitted from the emission layer is partially absorbed by the polarizing plate, and thus, the luminance is not lowered. Therefore, the display device 1 having a maximum luminance value of 2,000 nit or more may be provided.

The pixel defining layer 1170 may include a trench portion OP2.

The trench portion OP2 may be formed in the pixel defining layer 1170 and may be recessed toward the pixel electrode 211. For example, the trench portion OP2 may be recessed downward (a −z direction in FIGS. 7B and/or 7C) from the upper portion of the pixel defining layer 1170 toward the pixel electrode 211. In another aspect, the trench portion OP2 may be recessed in the pixel defining layer 1170 toward the pixel electrode 211.

The trench portion OP2 may be formed to overlap at least a portion of the pixel electrode 211.

In another aspect, it may be stated that the trench portion OP2 is formed in a portion where the pixel electrode 211 does not overlap the pixel defining layer 1170.

In an embodiment, the trench portion OP2 may be formed to expose at least a portion of the pixel electrode 211.

The pixel defining layer 1170 may include a first pixel defining layer 1171 and a second pixel defining layer 1172. For example, in case that the trench portion OP2 is formed to extend to and expose at least a portion of the pixel electrode 211, the first pixel defining layer 1171 and the second pixel defining layer 1172 may be divided based on the exposed portion of the pixel electrode 211, e.g., the portion of the pixel electrode 211 to which the trench portion OP2 extends.

The first pixel defining layer 1171 may refer to a portion disposed adjacent to the opening OP1. The second pixel defining layer 1172 may refer to a portion disposed on the opposite side of the first pixel defining layer 1171 with respect to the trench portion OP2.

In an embodiment, the first pixel defining layer 1171 and the second pixel defining layer 1172 may be spaced apart from each other. For example, the first pixel defining layer 1171 and the second pixel defining layer 1172 may be spaced apart from each other by the exposed width of the pixel electrode 211.

The first pixel defining layer 1171 may include a proximal portion 1171a and a distal portion 1171b at the lowermost end (the lowermost end in FIGS. 7B and/or 7C). The proximal portion 1171a of the first pixel defining layer 1171 may refer to a portion of the lowermost end closest to the opening OP1. The distal portion 1171b of the first pixel defining layer 1171 may refer to a portion of the lowermost end closest to the second pixel defining layer 1172. The second pixel defining layer 1172 may include a proximal portion 1172a at the lowermost end (the lowermost end in FIGS. 7B and/or 7C). The proximal portion 1172a of the second pixel defining layer 1172 may refer to a portion of the lowermost end closest to the first pixel defining layer 1171.

At this time, a distance W1 between the first pixel defining layer 1171 and the second pixel defining layer 1172 may refer to a distance between the distal portion 1171b of the first pixel defining layer 1171 and the proximal portion 1172a of the second pixel defining layer 1172.

In other embodiments, the first pixel defining layer 1171 and the second pixel defining layer 1172 may be spaced apart from each other by about 2.0 μm to about 2.2 μm. For example, the first pixel defining layer 1171 and the second pixel defining layer 1172 may be spaced apart from each other by about 2.2 μm. For example, the distal portion 1171b of the first pixel defining layer 1171 and the proximal portion 1172a of the second pixel defining layer 1172 may be spaced apart from each other by about 2.0 μm to about 2.2 μm. For example, the distal portion 1171b of the first pixel defining layer 1171 and the proximal portion 1172a of the second pixel defining layer 1172 may be spaced apart from each other by about 2.2 μm.

In case that the distance W1 between the first pixel defining layer 1171 and the second pixel defining layer 1172 is 2.0 μm to 2.2 μm, process dispersion may be optimized in the process of forming the trench portion OP2. For example, in case that the distance W1 between the first pixel defining layer 1171 and the second pixel defining layer 1172 is 2.0 μm to 2.2 μm, an inclination angle R2 of the trench portion OP2 of the first pixel defining layer 1171 may be formed to have an optimal angle, as described below.

In some embodiments, in case that the distance W1 between the first pixel defining layer 1171 and the second pixel defining layer 1172 is 2.0 μm to 2.2 μm, an effect of improving reflectivity due to the pixel defining layer 1170 may be significantly enhanced, as described below. For example, the specular component included (SCI) of light may be effectively reflected into an anti-reflection member 600.

In case that the distance W1 between the first pixel defining layer 1171 and the second pixel defining layer 1172 is less than 2.2 μm or greater than 2.2 μm, process dispersion may increase in the process of forming the trench portion OP2, or the SCI of light may not be effectively reflected into the anti-reflection member 600.

The color filter layer CF may be disposed adjacent to the anti-reflection member 600.

The color filter layer CF refers to a layer having coloring so as to include a plurality of pixels in the display device 1. For example, in case that light of a certain color is emitted from the emission layer 231b (see FIG. 6 for example), the color filter layer CF may allow only light of a desired color to be implemented while the light of the desired color passes through the color filter layer CF having coloring. The color to be implemented may be red, green, and/or blue.

As the anti-reflection member 600 is disposed adjacent to the color filter layer CF, the anti-reflection member 600 may absorb a color region other than the color to be implemented in the color filter layer CF, and thus, the color purity and contrast ratio may be increased.

In an embodiment, the pixel electrode 211 may be disposed to overlap the entire area of the first pixel defining layer 1171. For example, as illustrated in FIGS. 7B and 7C, the pixel electrode 211 may come into contact with the entire contact surface of the first pixel defining layer 1171. It may also be stated that the first pixel defining layer 1171 is formed on the pixel electrode 211.

In an embodiment, the pixel electrode 211 may be disposed to overlap at least a portion of the second pixel defining layer 1172. For example, the pixel electrode 211 may be disposed to overlap a portion of the second pixel defining layer 1172. For example, as illustrated in FIGS. 7B and 7C, a portion of the pixel electrode 211 may be disposed to overlap the second pixel defining layer 1172. It may also be stated that the second pixel defining layer 1172 is formed to cover a portion of the circumference of the pixel electrode 211.

The first pixel defining layer 1171 may be formed in a shape in which the width of the first pixel defining layer 1171 becomes narrower in a direction away from the pixel electrode 211 (a +z direction in FIGS. 7B and 7C). For example, the first pixel defining layer 1171 may be roughly formed in a dome shape.

In some embodiments, the first pixel defining layer 1171 may not include a flat portion. For example, all surfaces of the first pixel defining layer 1171, except for the portion which comes into contact with the pixel electrode 211, may be curved.

In this case, the problem of unintended light emission may be reduced as light incident on the first pixel defining layer 1171 is reflected on the flat portion and emitted to the outside through the opening OP1 or the like.

In an embodiment, a slope of the portion of the first pixel defining layer 1171 adjacent to the opening OP1 (hereinafter referred to as an opening slope) may be greater than a slope of the portion adjacent to the second pixel defining layer 1172 (hereinafter referred to as a trench slope). For example, in the first pixel defining layer 1171, an inclination angle R1 of the opening slope may be greater than an inclination angle R2 of the trench slope.

In other embodiments, in the first pixel defining layer 1171, the inclination angle R1 of the opening slope may be always greater than the inclination angle R2 of the trench slope at the same height with respect to the pixel electrode 211.

In an embodiment, the first pixel defining layer 1171 may be formed in a shape in which the inclination angle changes along the height direction (the z direction in FIGS. 7B and/or 7C). For example, the first pixel defining layer 1171 may have a different inclination angle at each height with respect to the pixel electrode 211.

In other embodiments, the inclination angle of the first pixel defining layer 1171 may gradually decrease in a direction away from the pixel electrode 211 (the z direction in FIGS. 7B and/or 7C). Accordingly, the first pixel defining layer 1171 may have an upwardly convex shape with the uppermost end formed gently, as illustrated in FIGS. 7B and/or 7C.

In other embodiments, the first pixel defining layer 1171 may be formed so that the inclination angle R1 of the opening slope is 30° to 45°. In case that the inclination angle R1 of the opening slope of the first pixel defining layer 1171 is 30° to 45°, the SCI of light may be effectively reflected into the anti-reflection member 600, and thus, reflection characteristics of the pixel PX may be improved. In case that the inclination angle R1 of the opening slope of the first pixel defining layer 1171 is less than 30°, the SCI of light may not be effectively reflected into the anti-reflection member 600, and thus, optical characteristics may not be improved. In case that the inclination angle R1 of the opening slope of the first pixel defining layer 1171 is greater than 45°, a short circuit may occur in the electrode (e.g., the opposite electrode 251).

In other embodiments, the first pixel defining layer 1171 may be formed so that the inclination angle R2 of the trench slope is 11° to 45°. In case that the inclination angle R2 of the trench slope of the first pixel defining layer 1171 is 11° to 45°, the SCI of light may be effectively reflected into the anti-reflection member 600, and thus, reflection characteristics of the pixel PX may be improved. In case that the inclination angle R2 of the trench slope of the first pixel defining layer 1171 is less than 11°, the SCI of light may not be effectively reflected into the anti-reflection member 600, and thus, optical characteristics may not be improved. In case that the inclination angle R2 of the trench slope of the first pixel defining layer 1171 is greater than 45°, a short circuit may occur in the electrode (e.g., the opposite electrode 251).

In an embodiment, the display device 1 may further include the anti-reflection member 600 disposed on the opposite electrode 251.

The anti-reflection member 600 may be disposed in at least one position of the display device 1 and perform a function of blocking light from being transmitted through an unintended portion. For example, the anti-reflection member 600 may prevent or reduce a light leakage phenomenon in which light emitted from the display element of the display element layer DPL (see FIG. 2 for example) disposed within the display device 1 is transmitted through the peripheral area PA of the display device 1. The anti-reflection member 600 may be referred to as a black matrix (BM) or a light leakage prevention member, but the anti-reflection member 600 is not limited to the terms or expressions.

The anti-reflection member 600 may include a light-absorbing material, or may include black pigment or black dye. In case that the anti-reflection member 600 is formed, carbon black or the like may be used as the black pigment or black dye, but the disclosure is not limited thereto.

The anti-reflection member 600 may absorb at least a portion of incident light. The light may be external light or reflected light reflected from the opposite electrode 251.

In an embodiment, the anti-reflection member 600 may be disposed on the touch sensing layer 400. At this time, separate layers configured to perform different functions may be further disposed between the anti-reflection member 600 and the touch sensing layer 400.

The anti-reflection member 600 may be disposed to overlap the second pixel defining layer 1172 and extend in a direction toward the trench portion OP2.

In an embodiment, the anti-reflection member 600 may be disposed to overlap the entire area of the pixel electrode 211 exposed by the trench portion OP2. For example, the anti-reflection member 600 may be disposed to overlap the entire area formed between the distal portion 1171b of the first pixel defining layer 1171 and the proximal portion 1172a of the second pixel defining layer 1172.

In other embodiments, the anti-reflection member 600 may be formed to extend further in a direction toward the opening OP1. For example, the anti-reflection member 600 may be formed to extend further in a direction from the distal portion 1171b of the first pixel defining layer 1171 toward the proximal portion 1171a. It may also be stated that a proximal portion 601 of the anti-reflection member 600 may be disposed closer to the opening OP1 than the distal portion 1171b of the first pixel defining layer 1171. Accordingly, at least a portion of the anti-reflection member 600 may be disposed to overlap the first pixel defining layer 1171.

In other embodiments, a width W2 of the area where the anti-reflection member 600 overlaps the first pixel defining layer 1171 may be 1.2 μm to 2.4 μm, and may be about 1.22 μm.

The above-described configuration may significantly enhance an effect of improving reflectivity due to the first pixel defining layer 1171. For example, as described below, external light or reflected light reflected from the opposite electrode 251 may be reflected on the first pixel defining layer 1171 and stably guided to the anti-reflection member 600. For example, in case that the width W2 of the area where the anti-reflection member 600 overlaps the first pixel defining layer 1171 is less than 1.2 μm, the anti-reflection member 600 may not completely block the inclined surface of the second pixel defining layer 1172. Thus, external light or reflected light reflected from the opposite electrode 251 may not be stably guided to the anti-reflection member 600. For example, in case that the width W2 of the area where the anti-reflection member 600 overlaps the first pixel defining layer 1171 is greater than 2.4 μm, the anti-reflection member 600 may excessively cover the inclined surface of the second pixel defining layer 1172. Thus, external light or reflected light reflected from the opposite electrode 251 may not be stably guided to the anti-reflection member 600.

In some embodiments, the trench portion OP2 may be formed to have a shape with an optimized reflectivity improvement effect, despite errors which may occur during a manufacturing process.

Furthermore, the reflectivity improvement effect due to the trench portion OP2 may be significantly enhanced. For example, as described below, external light or reflected light reflected from the opposite electrode 251 may be reflected on the first pixel defining layer 1171 and stably guided to the anti-reflection member 600.

Referring again to FIGS. 8A to 8D and 9, the trench portion OP2 may be formed by a photolithography process.

A photomask M1 may be used to form the trench portion OP2.

The photomask M1 used to form the trench portion OP2 may include a full-tone dark area FTDKA and an open area OPA. As illustrated in FIG. 8A, the photomask M1 may be formed by the full-tone dark area FTDKA, the open area OPA, and the full-tone dark area FTDKA, which are alternately formed from the center of the photomask M1.

The full-tone dark area FTDKA may refer to an area which prevents the overlapping area from being light-exposed by blocking light emitted in the photolithography process. In contrast, the open area OPA may refer to an area which allows the overlapping area to be fully light-exposed by transmitting light emitted in the photolithography process.

The photomask M1 used to form the trench portion OP2 may have the full-tone dark areas FTDKA disposed in areas corresponding to the opening OP1 and the trench portion OP2. For example, the photomask M1 may prevent the areas corresponding to the opening OP1 and the trench portion OP2 from being light-exposed in the photolithography process.

In other embodiments, a width W3 of the full-tone dark area FTDKA disposed at a position corresponding to the trench portion OP2 may be greater than a width of the pixel electrode 211 exposed by the trench portion OP2.

In other embodiments, the full-tone dark area FTDKA disposed at a position corresponding to the opening OP1 may overlap the first pixel defining layer 1171 by a width W4.

Accordingly, the trench portion OP2 with an optimized reflectivity improvement effect may be formed, despite errors which may occur during the process of forming the trench portion OP2.

In a plan view, the trench portion OP2 may have a circular ring shape or an elliptical ring shape. Accordingly, the first pixel defining layer 1171 may also have a circular ring shape or an elliptical ring shape.

The first pixel defining layer 1171, the trench portion OP2, and the second pixel defining layer 1172 may be formed by a photolithography process. The photolithography process may be a positive photoresist (positive PR) process or a negative photoresist (negative PR) process.

Because the planar shape of the photomask M1 used in the photolithography process includes a circular ring shape or an elliptical ring shape, the trench portion OP2 and the first pixel defining layer 1171, of which the planar shape includes a circular ring shape or an elliptical ring shape, may be formed.

For example, FIG. 8A is a diagram illustrating the photomask M1 for forming the first pixel defining layer 1171 and the trench portion OP2 each having a circular ring shape in a plan view when the photolithography process is a negative PR process. For example, the trench portion OP2 having the circular ring shape and the first pixel defining layer 1171 having the circular ring shape may be formed through the photolithography process using the photo mask M1 in which the full tone dark area FTDKA has a circular shape and the open area OPA has a circular ring shape. FIG. 8C is a diagram illustrating the trench portion OP2 having a circular ring shape and the first pixel defining layer 1171 having a circular ring shape, which are formed by the photolithography process using the photomask M1 in FIG. 8A.

FIG. 8B is a diagram illustrating the photomask M1 for forming the first pixel defining layer 1171 and the trench portion OP2 each having an elliptical ring shape in a plan view when the photolithography process is a negative PR process. For example, the trench portion OP2 having the elliptical ring shape and the first pixel defining layer 1171 having the elliptical ring shape may be formed through the photolithography process using the photo mask M1 in which the full tone dark area FTDKA has an elliptical shape and the open area OPA has an elliptical ring shape. FIG. 8D is a diagram illustrating the trench portion OP2 having an elliptical ring shape and the first pixel defining layer 1171 having an elliptical ring shape, which are formed by the photolithography process using the photomask M1 in FIG. 8B.

FIG. 8E shows a result of performing a diffraction and glare simulation on a light source in an emission area defined by a circular opening of a pixel defining layer where no trench portion is formed (Ref), an emission area defined by an elliptical opening of a pixel defining layer where no trench portion is formed (Case 1), an emission area defined by a circular opening of a pixel defining layer where a trench portion is formed (Case 2), or an emission area defined by an elliptical opening of a pixel defining layer where a trench portion is formed (Case 3). The circular or elliptical opening OP1 refers to a shape in a plan view. In some embodiments, in case that the circular opening OP1 in a plan view is formed and the pixel defining layer 1170 includes the trench portion OP2, the trench portion OP2 has a circular ring shape in a plan view and the first pixel defining layer 1171 has a circular ring shape in a plan view. In some embodiments, in case that the elliptical opening OP1 in a plan view is formed and the pixel defining layer 1170 includes the trench portion OP2, the trench portion OP2 has an elliptical ring shape in a plan view and the first pixel defining layer 1171 has an elliptical ring shape in a plan view.

For example, the comparison in FIG. 8E represents the relative light intensity as the relative distance from the light source expressed in angle in the display device 1 increases. The relative distance from the light source expressed in angle refers to a ratio of a tangent value of the angle. For example, the ratios of 10° and 15° with respect to the distance from the light source are respectively tan(10°) and tan(15°).

In the emission area defined by the elliptical opening OP1, diffraction of the light source may be reduced when the relative distance is 10° to 15°.

For example, as a result of simulation, it may be confirmed from comparison between Ref and Case 1 that, when the relative distance from the light source is 10° to 15°, diffraction of the light source may be reduced in the emission area defined by the elliptical opening OP1, compared to the emission area defined by the circular opening OP1.

When comparing Ref with Case 1 in FIG. 8E, in the case of Ref, when the relative distance from the light source is 10° to 15°, the maximum value of the relative light intensity is 2.56 and the minimum value of the relative light intensity is 0.59. Accordingly, the difference (i.e., peak-to-peak) between the maximum value and the minimum value of the relative light intensity is 1.86. However, in the case of Case 1, when the relative distance from the light source is 10° to 15°, the maximum value of the relative light intensity is 2.34 and the minimum value of the relative light intensity is 0.92. Accordingly, the difference (i.e., peak-to-peak) between the maximum value and the minimum value of the relative light intensity is reduced to 1.41.

Therefore, in the case of Case 1, it may be confirmed that the diffraction toward the light source is reduced when the relative distance from the light source is 10° to 15°, compared to Ref.

Similarly, it may be confirmed from comparison between Case 2 and Case 3 that, when the relative distance from the light source is 10° to 15°, diffraction of the light source may be reduced in the emission area defined by the elliptical opening OP1, compared to the emission area defined by the circular opening OP1.

When comparing Case 2 with Case 3 in FIG. 8E, in the case of Case 2, when the relative distance from the light source is 10° to 15°, the maximum value of the relative light intensity is 2.66 and the minimum value of the relative light intensity is 0.90. Accordingly, the difference (i.e., peak-to-peak) between the maximum value and the minimum value of the relative light intensity is 1.76. However, in the case of Case 3, when the relative distance from the light source is 10° to 15°, the maximum value of the relative light intensity is 2.20 and the minimum value of the relative light intensity is 1.07. Accordingly, the difference (i.e., peak-to-peak) between the maximum value and the minimum value of the relative light intensity is reduced to 1.41.

Therefore, in the case of Case 3, it may be confirmed that the diffraction toward the light source is reduced when the relative distance from the light source is 10° to 15°, compared to Case 2.

In some embodiments, referring to FIG. 8E, it may be seen that, in the case of the pixel defining layer in which the trench portion OP2 is formed (Cases 2 and 3), glare is reduced, compared to the case of the pixel defining layer in which the trench portion OP2 is not formed (Ref and Case 1).

Specifically, when the relative distance from the light source is 10° or less, the relative light intensity decreases in Case 2, compared to Ref. This means that glare is reduced.

When the relative distance from the light source is 10° or less, the relative light intensity decreases in Case 3, compared to Case 1. This means that glare is reduced.

Therefore, the display device 1 including the elliptical pixel defining layer 1170 in which the trench portion OP2 is formed may have an effect of reducing glare when the relative distance from the light source is 10° or less and reducing diffraction of the light source when the relative distance from the light source is 10° to 15°, compared to the display device 1 including the circular pixel defining layer 1170 in which the trench portion OP2 is not formed.

FIG. 8F is a diagram illustrating a distance between adjacent trench portions according to an embodiment. FIG. 8G is a diagram illustrating that a second pixel defining layer between adjacent trench portions in FIG. 8F has been removed. FIG. 8H is a diagram illustrating that a second pixel defining layer does not exist between adjacent trench portions, according to an embodiment. FIG. 8I is a diagram illustrating a trench portion and a transmission opening according to an embodiment. FIG. 8J is a cross-sectional view illustrating an example of a VI-VI′ cross-section of FIG. 8I. FIG. 8K is a diagram illustrating that a second pixel defining layer between the trench portion and the transmission opening in FIG. 8I has been removed. FIG. 8L is a diagram illustrating that a second pixel defining layer does not exist between a transmission opening and a trench portion, according to an embodiment. FIG. 8M is a diagram illustrating that the second pixel defining layer adjacent to the transmission opening in FIG. 8L has been removed. FIG. 8N is another diagram illustrating that the second pixel defining layer adjacent to the transmission opening in FIG. 8L has been removed.

Referring to FIGS. 8F to 8N, a distance L1 between the trench portions OP2 of the adjacent pixels PX in the display device 1 according to an embodiment may be greater than 5.2 μm.

In the display device 1 according to an embodiment, the distance between the adjacent trench portions OP2 may vary depending on a resolution.

For example, when the resolution of the display device 1 according to an embodiment is less than 500 ppi, the distance L1 between the adjacent trench portions OP2 may be greater than about 5.2 μm, when the resolution of the display device 1 according to an embodiment is about 500 ppi, the distance L1 between the adjacent trench portions OP2 may be about 5.2 μm, and when the resolution of the display device 1 according to an embodiment is greater than about 500 ppi, the distance L1 between the adjacent trench portions OP2 may be about 5.2 μm or less.

In some embodiments, the distances L1 and L3 between the trench portions OP2 of the adjacent pixels PX in the display device 1 according to an embodiment are 5.2 μm or less, and the second pixel defining layer 1172 existing between the adjacent trench portions OP2 may be removed and the connection portions P1 and P3 connecting the adjacent trench portions OP2 may be included.

For example, when the distance L1 between the adjacent trench portions OP2 in the display device 1 according to an embodiment is about 5.2 μm or less, the second pixel defining layer 1172 existing between the adjacent trench portions OP2 may be removed and the first connection portion P1 connecting the adjacent trench portions OP2 may be included (see FIG. 8G).

In some embodiments, in the display device 1 according to an embodiment, the width of the trench portion OP2 may be expanded so that no second pixel defining layer 1172 exists between the adjacent trench portions OP2 (see FIG. 8H).

The display device 1 according to an embodiment may include a transmission opening OP3. The transmission opening OP3 refers to an area that does not overlap the pixel defining layer 1170 and the anti-reflection member 600 in a plan view of the second insulating layer 116. The opposite electrode 251 and the encapsulation member 300 may be disposed on the transmission opening OP3. Light generated from the optical element may be transmitted through the transmission opening OP3 and emitted to the outside of the display device 1 through the first component area EA1. In this case, the transmission opening OP3 may exist between the trench portions OP2 of the adjacent pixels PX.

In the display device 1 including the transmission opening OP3, according to an embodiment, a distance L2 between the transmission opening OPS and the adjacent trench portion OP2 and a distance L3 between the adjacent trench portions OP2 may vary depending on a resolution.

For example, when the resolution of the display device 1 according to an embodiment is less than about 500 ppi, the distance L2 between the transmission opening OP3 and the trench portion OP2 may be greater than about 5.2 μm, when the resolution of the display device 1 according to an embodiment is about 500 ppi, the distance L2 between the transmission opening OP3 and the trench portion OP2 may be about 5.2 μm or less, and when the resolution of the display device 1 according to an embodiment is about 500 ppi or more, the second pixel defining layer 1172 may not exist between the transmission opening OP3 and the trench portion OP2.

In the display device 1 including the transmission opening OP3, according to an embodiment, in case that the distance L2 between the transmission opening OP3 and the trench portion OP2 is about 5.2 μm or less, the second pixel defining layer 1172 existing between the transmission opening OP3 and the trench portion OP2 may be removed and a second connection portion P2 connecting the adjacent transmission opening OP3 to the trench portion OP2 may be included (see FIG. 8K).

In some embodiments, in case that the distance L3 between the adjacent trench portions OP2 in the display device 1 including the transmission opening OP3, according to an embodiment, is about 5.2 μm or less, the second pixel defining layer 1172 may not exist between the transmission opening OP3 and the trench portion OP2 (see FIG. 8L).

In some embodiments, the display device 1 including the transmission opening OP3, according to an embodiment, in case that the distance L3 between the adjacent trench portions OP2 is about 5.2 μm or less, the second pixel defining layer 1172 existing between the adjacent trench portions OP2 may be removed and a third connection portion P3 connecting the adjacent transmission openings OP3 may be included (see FIG. 8M).

In some embodiments, in the display device 1 including the transmission opening OP3, according to an embodiment, the width of the trench portion OP2 may be expanded so that no second pixel defining layer exists between the adjacent trench portions OP2 (see FIG. 8N).

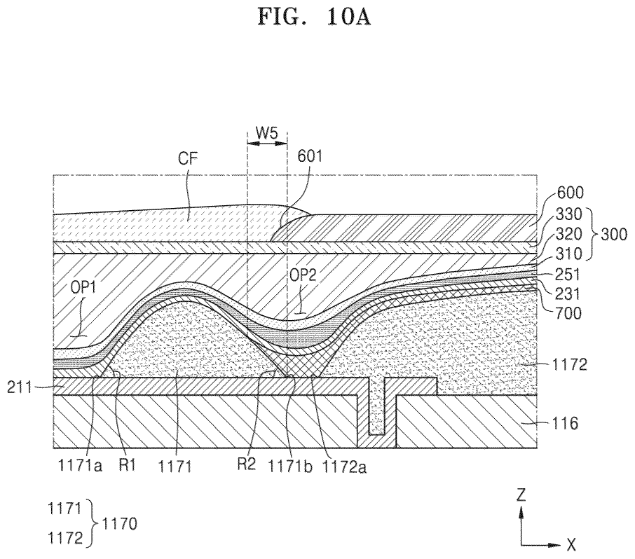

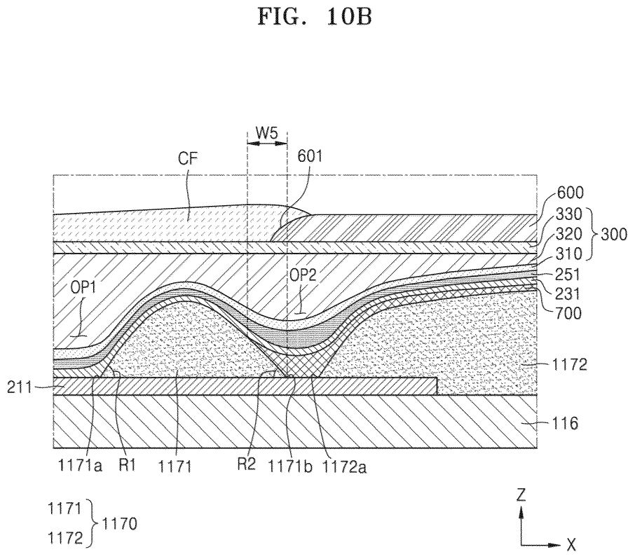

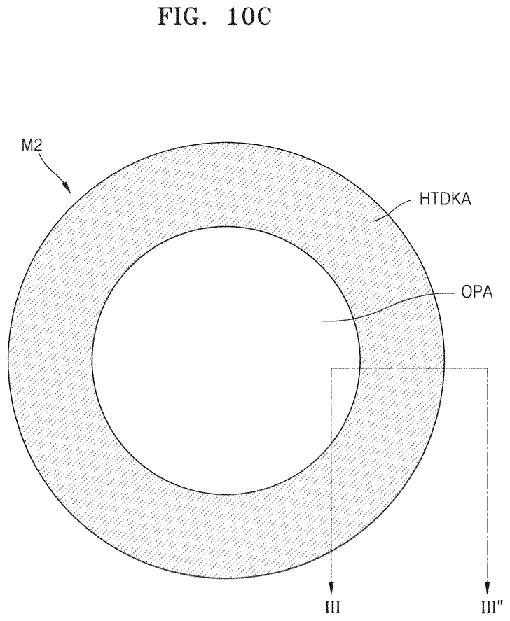

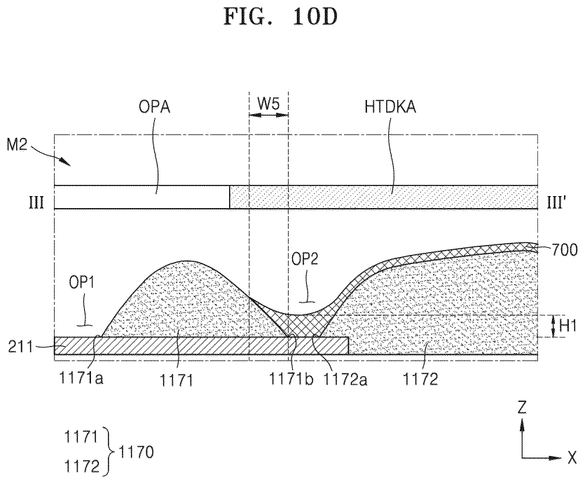

FIG. 10A is a diagram for describing a pixel defining layer on which a capping layer is formed, according to an embodiment. FIG. 10B is another diagram for describing a pixel defining layer on which a capping layer is formed, according to an embodiment. FIG. 10C is a diagram schematically illustrating an embodiment of a photomask used to form the capping layer of FIG. 10A or 10B. FIG. 10D is a diagram for describing a process of forming the capping layer of FIG. 10A or 10B and of a III-III″ cross-section of FIG. 10C.

For example, FIG. 10A may be a cross-sectional view schematically illustrating an example of the IV-IV′ cross-section of FIG. 7A, and FIG. 10B may be a cross-sectional view schematically illustrating an example of the V-V′ cross-section of FIG. 7A.

Hereinafter, for convenience of explanation, contents which are the same as provided above or may be easily applied by those of ordinary skill in the art are omitted or briefly described.

Referring to FIGS. 10A to 10D, a capping layer 700 may be further disposed on the trench portion OP2.

The capping layer 700 may be formed on the trench portion OP2. For example, the capping layer 700 may be formed to cover at least a portion of the trench portion OP2.

In an embodiment, the capping layer 700 may cover the entire area of the pixel electrode 211 exposed by the trench portion OP2. For example, the capping layer 700 may cover the entire area of the pixel electrode 211 exposed by the trench portion OP2, so as to substantially prevent the pixel electrode 211 from being exposed to the outside.

In an embodiment, the capping layer 700 may also be formed on the second pixel definition film 1172. For example, the capping layer 700 may be formed to cover at least a portion of the second pixel defining layer 1172. It may be confirmed from FIG. 10A or 10B that the capping layer 700 is formed to cover both the trench portion OP2 and the second pixel defining layer 1172.

In an embodiment, the capping layer 700 may include a material that is different from a material of the pixel defining layer 1170. In other embodiments, the capping layer 700 may include a same material as a material of the spacer. In other embodiments, the capping layer 700 may include PI.

Accordingly, in case that the trench portion OP2 is formed in the photolithography process as described below, a pattern structure of the trench portion OP2 may be regularly formed according to light exposure sensitivity and the inclination angle of the trench portion OP2 may be optimally formed.

In an embodiment, at least a portion of the capping layer 700 may be formed to overlap the first pixel defining layer 1171.

In other embodiments, a width W5 of the area where the capping layer 700 overlaps the first pixel defining layer 1171 may be greater than 0 μm and less than or equal to 2.0 μm. For example, the width W5 may be about 1.0 μm. In case that the width W5 of the area where the capping layer 700 overlaps the first pixel defining layer 1171 is greater than 2.0 μm, the SCI of light L is not reduced. Accordingly, the SCI of the light L may not be effectively reflected into the anti-reflection member 600. For example, in case that the width W5 of the area where the capping layer 700 overlaps the first pixel defining layer 1171 is greater than 2.0 μm, a thickness H1 of the capping layer 700 described below may excessively increase, and thus, the inclination angle R1 of the opening slope and the inclination angle R2 of the trench slope may have values which do not contribute to improving optical characteristics.

In other embodiments, the thickness H1 of the capping layer 700 may be about 0.4 μm to about 0.8 μm. The thickness H1 of the capping layer 700 may refer to a thickness from the exposed portion of the pixel electrode 211 in the vertical direction (the z direction in FIG. 1). The improvement in optical characteristics according to the thickness H1 of the capping layer 700 is described below.

Due to the above-described configuration, the capping layer 700 may prevent or reduce a problem in that dark spots occur due to the trench portion OP2. The capping layer 700 may also protect the pixel electrode 211 exposed by the trench portion OP2.

Referring again to FIGS. 10C and 10D, the capping layer 700 may be formed by a photolithography process.

A photomask M2 may be used to form the capping layer 700.

The photomask M2 used to form the capping layer 700 may include a half-tone dark area HTDKA and an open area OPA. As illustrated in FIG. 10C, the photomask M2 may have the open area OPA and the half-tone dark area HTDKA, which are formed from the center of the photomask M2.

The half-tone dark area HTDKA may refer to an area which reduces the amount of light exposure in the overlapping area by blocking a portion of light emitted in the photolithography process. In contrast, the open area OPA may refer to an area which allows the overlapping area to be fully light-exposed by transmitting light emitted in the photolithography process.

The photomask M2 used to form the capping layer 700 may be formed so that the half-tone dark area HTDKA extends outward from an area corresponding to a portion of the first pixel defining layer 1171. Due to the photomask M2, a portion of the first pixel defining layer 1171 and the second pixel defining layer 1172 may be relatively weakly light-exposed in the photolithography process by a portion of light used in the photolithography process.

In other embodiments, the half-tone dark area HTDKA may extend further toward the opening OP1 than the area where the capping layer 700 is formed on the first pixel defining layer 1171. In FIG. 10D, the half-tone dark area HTDKA may extend further to the left (in the direction toward the opening OP1) from the left boundary of the capping layer 700.

Accordingly, the capping layer 700 with an improved dark spot improvement effect may be formed despite errors which may occur in the process of forming the capping layer 700.

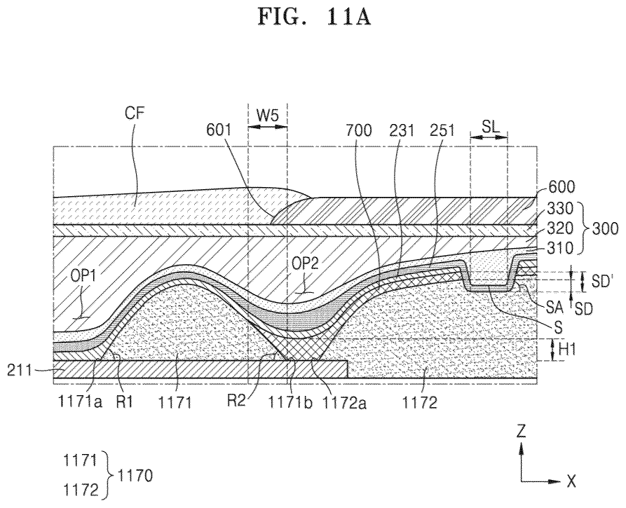

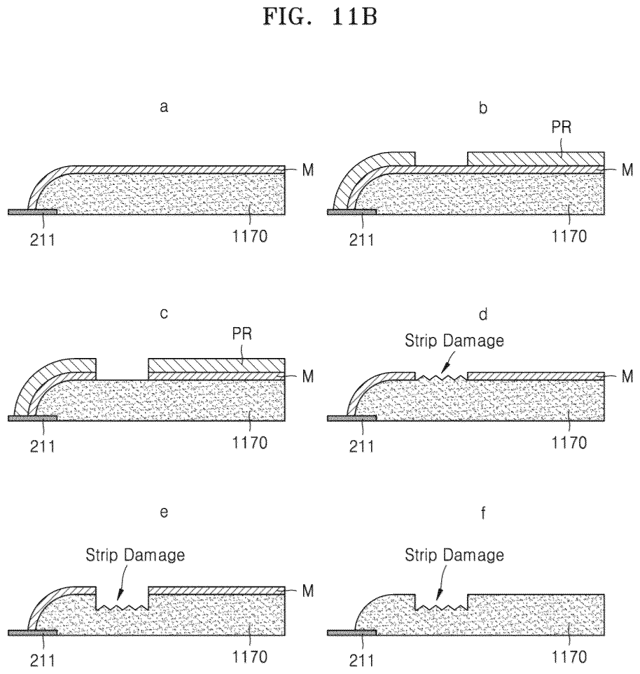

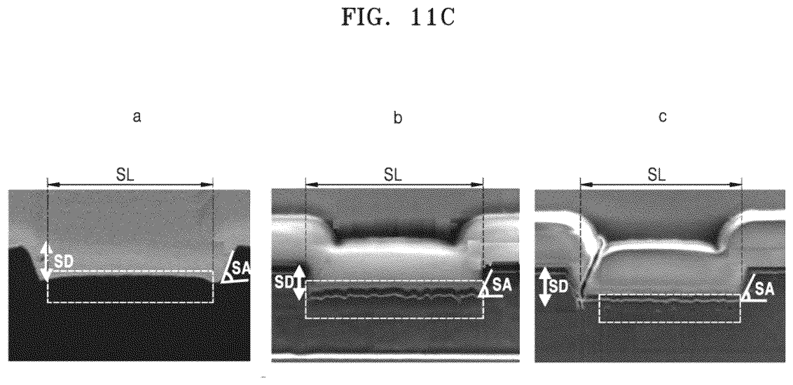

FIG. 11A is a diagram for describing a pixel defining layer 1170 on which a separator S is formed according to an embodiment. FIG. 11B is a schematic diagram illustrating a process of forming the separator S in a pixel defining layer 1170 according to an embodiment. FIG. 11C is a photograph of the separator S formed in the pixel defining layer 1170 according to an embodiment.

Referring to FIGS. 11A to 11C, the pixel defining layer 1170 according to an embodiment may include the separator S recessed into the pixel defining layer 1170. For example, a second pixel defining layer 1172 may include the separator S recessed into the second pixel defining layer 1172.

An opposite electrode 251 may be disposed on the pixel defining layer 1170. For example, the opposite electrode 251 may be formed on the entire pixel defining layer 1170 while extending toward a first pixel defining layer 1171, a trench portion OP2, and the second pixel defining layer 1172.

The separator S may prevent lateral leakage current between adjacent pixels PX by short-circuiting the adjacent opposite electrodes 251. The adjacent opposite electrodes 251 may have a disconnected shape with respect to the separator S.

A first depth SD of the separator S may be about 0.3 μm to about 0.7 μm. For example, the first depth SD of the separator S may be about 0.5 μm. The first depth SD of the separator S refers to a vertical distance recessed when the separator S is formed in the pixel defining layer 1170.

In case that the first depth SD of the separator S is 0.3 μm to 0.7 μm, the lateral leakage current prevention effect of the separator S may be excellent. In case that the first depth SD of the separator S is less than 0.3 μm, the lateral leakage current prevention effect of the separator S may not be excellent, and in case that the first depth SD of the separator S is greater than 0.7 μm, electrical characteristics of the display device 1 may deteriorate.

The separator S may include a separator length portion SL which is recessed into the pixel defining layer 1170 and is substantially flat.

In this case, an angle SA formed by the separator length portion SL and the adjacent pixel defining layer 1170 may be about 70° to about 85°.

The lateral leakage current prevention effect of the separator S may not be excellent in case that the angle SA formed by the separator length portion SL and the adjacent pixel defining layer 1170 is less than 70°.

Referring to FIG. 11B, the separator S may be formed in the pixel defining layer 1170 by forming a metal layer M (e.g., indium gallium zinc oxide (IGZO)) on the pixel defining layer 1170) (operation (a)), applying photoresist PR on the metal layer M (operation (b)), etching a portion of the metal layer M through a photolithography process (operation (c)), removing the photoresist PR (operation (d)), forming the separator S by performing an etching process on the pixel defining layer 1170 (operation (e)), and removing the metal layer M by performing etching thereon (operation (f)). The etching in operation (c) and/or operation (f) may be wet etching, and the etching in operation (e) may be dry etching.

In this case, while operations (d) to (f) are performed, strip damage may occur in the separator length portion SL and the roughness of the separator length portion SL may increase. In case that the roughness of the separator length portion SL increases, the adjacent opposite electrodes 251 may not be completely short-circuited, and thus, the lateral leakage current prevention effect between the adjacent pixels PX may deteriorate.

According to an embodiment, the pixel defining layer 1170 may form the separator S after the capping layer 700 is formed on the pixel defining layer 1170. For example, the second pixel defining layer 1172 may include the separator S recessed into the second pixel defining layer 1172, the capping layer 700 may be formed to extend from the trench portion OP2 and cover the separator S, and then, the pixel defining layer 1170 may form the separator S while operations (a) to (f) of FIG. 11B are performed. In this case, as a portion of the capping layer 700 formed on the second pixel defining layer 1170 is removed, the separator S recessed into the second pixel defining layer 1170 may be formed.

In this case, a second depth SD′ of the separator S may be about 0.3 μm to about 0.7 μm. For example, the second depth SD′ of the separator S may be about 0.5 μm. The second depth SD′ of the separator S refers to a vertical distance recessed when the separator S is formed in the pixel defining layer 1170 on which the capping layer 700 is formed.

In case that the second depth SD′ of the separator S is 0.3 μm to 0.7 μm, the lateral leakage current prevention effect of the separator S may be excellent. In case that the second depth SD′ of the separator S is less than 0.3 μm, the lateral leakage current prevention effect of the separator S may not be excellent, and in case that the second depth SD′ of the separator S is greater than 0.7 μm, electrical characteristics of the display device 1 may deteriorate.

In this case, the opposite electrode 251 may be formed on an intermediate layer 231 and the separator S. For example, in case that the capping layer 700 is formed on the pixel defining layer 1170 and the separator S is then formed, the intermediate layer 231 may be formed on the capping layer 700 while extending from the first pixel defining layer 1171, on which the capping layer 700 is not formed, toward the second pixel defining layer 1172, and the opposite electrode 251 may be formed on all or part of the intermediate layer 231 and may also be formed on the separator S.

According to an embodiment, in case that the capping layer 700 is formed on the pixel defining layer 1170 and the separator S is then formed, the roughness of the separator length portion SL may be reduced and the adjacent opposite electrodes 251 are short-circuited, which may improve the lateral leakage current prevention effect.

FIG. 11C is a photograph of the separator S formed on the pixel defining layer 1170, according to an embodiment. Specifically, (a) of FIG. 11C is a photograph in case that the capping layer 700 is formed on the pixel defining layer 1170 and the separator S is then formed, and (b) and (c) of FIG. 11C are photographs in case that the separator S is formed on the pixel defining layer 1170 on which the capping layer 700 is not formed.

Referring to FIG. 11C, it may be confirmed that the roughness of the separator length portion SL is further reduced in case that the separator S is formed on the pixel defining layer 1170 on which the capping layer 700 is formed than in case that the separator S is formed on the pixel defining layer 1170 on which the capping layer 700 is not formed.

Accordingly, in case that the separator S is formed on the pixel defining layer 1170 on which the capping layer 700 is formed, the adjacent opposite electrodes 251 are short-circuited, which may improve the lateral leakage current prevention effect.

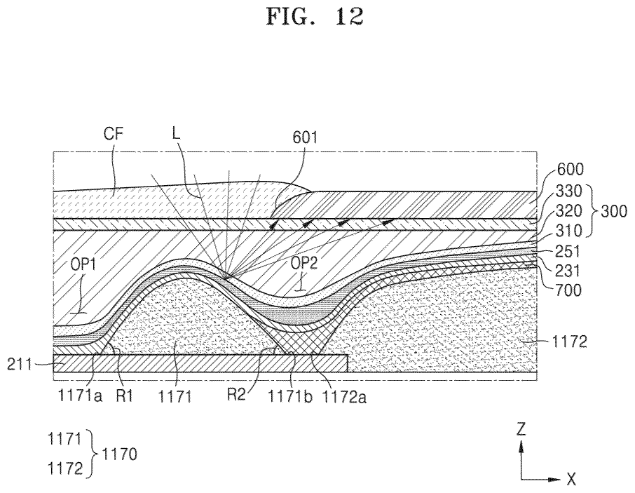

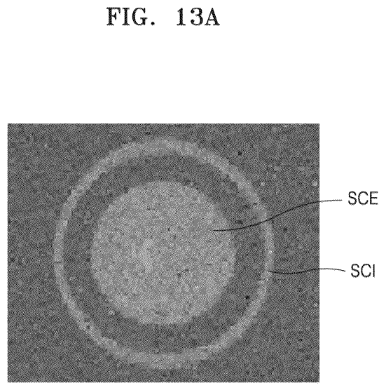

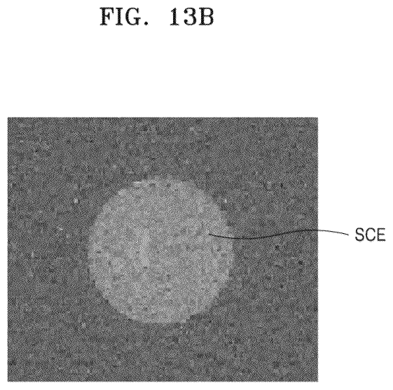

FIG. 12 is a diagram for describing a reflection path of light in a display device according to the disclosure. FIGS. 13A and 13B are photographs for describing an effect of improving optical characteristics in the display device of FIG. 12. FIG. 13A is a photograph of reflected light of light L in case that the trench portion OP2 is not formed and FIG. 13B is a photograph of reflected light of light L in case that the trench portion OP2 is formed.

Referring to FIG. 12, the light L incident on the pixel defining layer 1170 may be reflected from the pixel defining layer 1170 and then guided to the anti-reflection member 600. For example, the light L incident on the first pixel defining layer 1171 may be reflected from the first pixel defining layer 1171 and then guided to the anti-reflection member 600. Although not illustrated, the opposite electrode 251 may be disposed on at least a portion of the pixel defining layer 1170, as described above. In this case, the light L incident on the opposite electrode 251 may be reflected from the opposite electrode 251 and then guided to the anti-reflection member 600. For example, the light L incident on the opposite electrode 251 may be reflected from the opposite electrode 251 and then guided to the anti-reflection member 600.

The light L incident on the pixel defining layer 1170 or the opposite electrode 251 may include external light or reflected light reflected from the opposite electrode 251.

Referring to FIG. 12, the light L incident on the pixel defining layer 1170 may be reflected from the opposite electrode 251. At this time, the light L which is specularly reflected in the flat area of the opposite electrode 251 among pieces of reflected light may be defined as specular component included (SCI), and the light L which is diffusely reflected in the curved area of the opposite electrode 251 may be defined as specular component excluded (SCE).

In this case, as illustrated in FIG. 13A, in case that the reflected light includes a large amount of the SCI of the light L, unintended output light may be externally displayed. For example, in case that the pixel defining layer 1170 has a flat area, a portion of the light L may be specularly reflected from the flat area and emitted to the outside, which may cause a halo or diffraction pattern, as illustrated in FIG. 13A.

In contrast, in case that the pixel defining layer 1170 includes the trench portion OP2 and thus does not have a flat area, a significant portion of the light L incident on the pixel defining layer 1170 may be diffusely reflected and guided to the anti-reflection member 600. Accordingly, the SCI of the light L emitted by the pixel may be reduced, which may improve optical characteristics of the display device 1. For example, as illustrated in FIG. 13B, because the SCI of the light L is reduced, a problem in that unintended output light is externally displayed may be solved and optical characteristics may be improved.

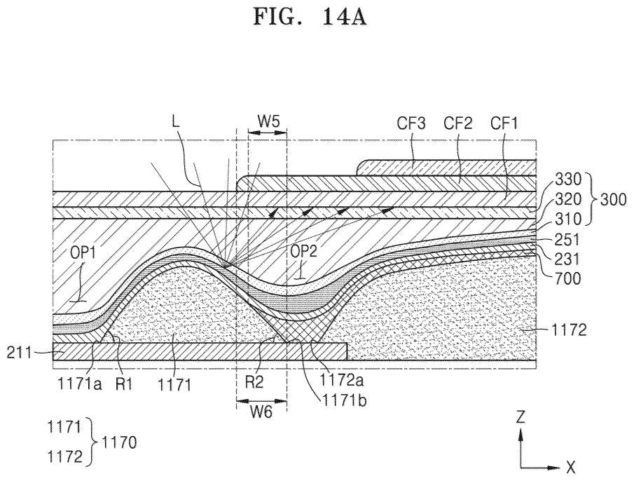

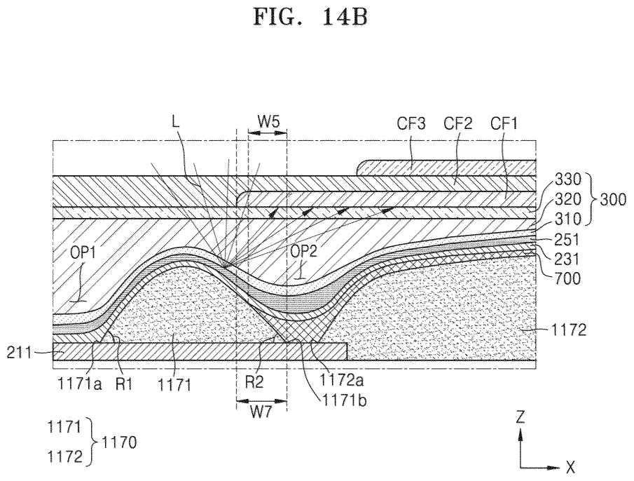

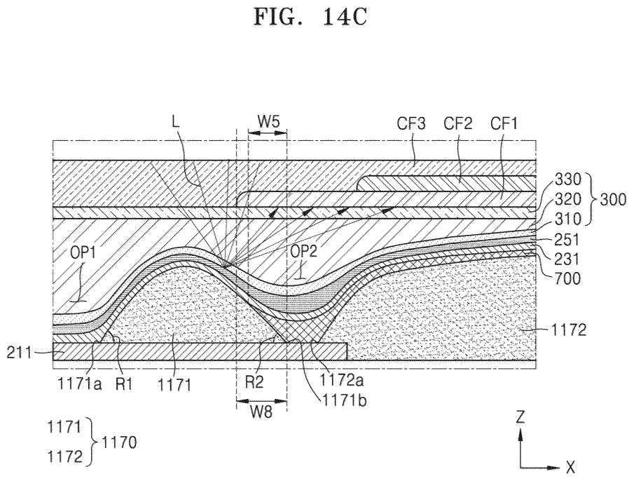

FIGS. 14A to 14C are diagrams illustrating embodiments in which the anti-reflection member is removed in the display device according to the disclosure.

Referring to FIGS. 14A to 14C, the anti-reflection member 600 (see FIG. 12 for example) may be removed in the display device according to the disclosure.

A first color filter CF1 may be a color filter CF which implements blue, a second color filter CF2 may be a color filter CF which implements red, and a third filter CF3 may be a color filter CF which implements green. The color filters CF1, CF2, and CF3 of different colors may be stacked to act as the anti-reflection member 600.

For example, light L incident on the pixel defining layer 1170 may be reflected from the pixel defining layer 1170 and then guided to an area where the first color filter CF1 overlaps the second color filter CF2. The area where the first color filter CF1 overlaps the second color filter CF2 may act as the anti-reflection member 600.

In case that the first color filter CF1, the second color filter CF2, and the third color filter CF3 are color filters CF which implement blue, red, and green, respectively, and the intermediate layer 231 emits blue light, the plurality of color filters CF1, CF2, and CF3 may be stacked as illustrated in FIG. 14A. In case that the intermediate layer 231 emits red light, the plurality of color filters CF1, CF2, and CF3 may be stacked as illustrated in FIG. 14B. In case that the intermediate layer 231 emits green light, the plurality of color filters CF1, CF2, and CF3 may be stacked as illustrated in FIG. 14C.

In some embodiments, a width W6 of the area where the second color filter CF2 overlaps the first pixel defining layer 1171 may be wider than a width W5 of the area where the capping layer 700 overlaps the first pixel defining layer 1171 (see FIG. 14A). A width W7 of the area where the first color filter CF1 overlaps the first pixel defining layer 1171 may be wider than the width W5 of the area where the capping layer 700 overlaps the first pixel defining layer 1171 (see FIG. 14B). A width W8 of the area where the first color filter CF1 overlaps the first pixel defining layer 1171 may be wider than the width W5 of the area where the capping layer 700 overlaps the first pixel defining layer 1171 (see FIG. 14C).

In case that the width W6, W7, or W8 of the area where the first color filter CF1 or the second color filter CF2 overlaps the first pixel defining layer 1171 is wider than the width W5 of the area where the capping layer 700 overlaps the first pixel defining layer 1171, the light L incident on the pixel defining layer 1170 may be reflected from the pixel defining layer 1170 and then guided to the area where the first color filter CF1 overlaps the second filter CF2, even when taking into account the tolerance when forming the plurality of color filters CF1, CF2, and CF3. Accordingly, the area where the first color filter CF1 overlaps the second color filter CF2 may act as the anti-reflection member 600.

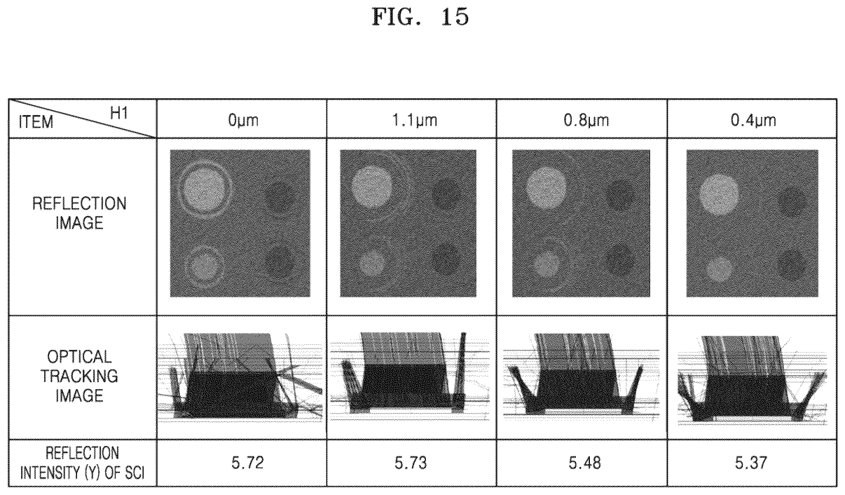

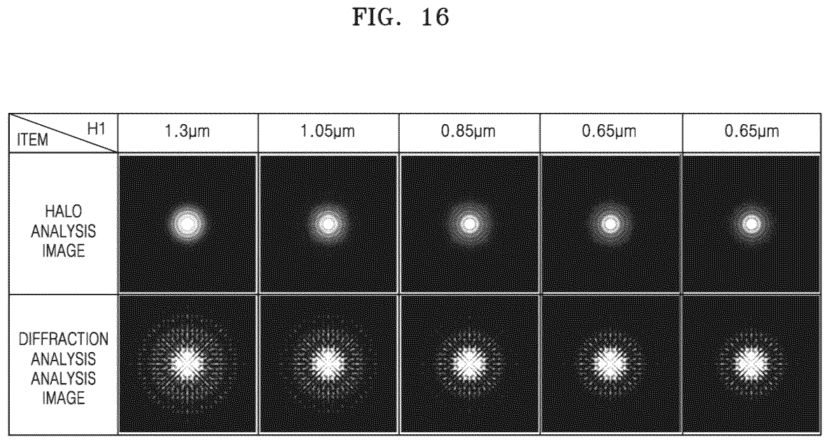

FIGS. 15 and 16 are tables for describing an effect of improving optical characteristics according to the thickness of the capping layer. FIG. 15 is a table which organizes a reflection image, a light tracing image, and reflection intensity (Y) of SCI according to the thickness of the capping layer. FIG. 16 is a table which organizes a halo analysis image and a diffraction analysis image according to the thickness of the capping layer.

Referring to FIG. 15, in case that the thickness H1 of the capping layer 700 is 0 μm, it may be confirmed that the SCI of the light L increases and an image due to the SCI is formed outside the reflection image. The expression “the thickness H1 of the capping layer 700 is 0 μm” may mean that the capping layer 700 is not formed. This may mean that a portion of the pixel electrode 211 is completely exposed. Furthermore, referring to FIG. 15, it may be confirmed from the reflection image that, as the thickness H1 of the capping layer 700 decreases, the image due to the SCI becomes blurred. This may mean that the SCI is reduced. It may be confirmed that, in case that the thickness H1 of the capping layer 700 is 0.8 μm or less, the image due to the SCI becomes significantly blurred. In case that the thickness H1 of the capping layer 700 is less than 0.4 μm, a portion of the pixel electrode 211 may be completely exposed, by taking into account process dispersion. Therefore, the thickness H1 of the capping layer 700 may be 0.4 μm or more. Referring to the optical tracing image of FIG. 15, it may be confirmed that, in case that the thickness H1 of the capping layer 700 is 0 μm or 0.8 μm or more, a significant amount of reflected light is specularly reflected upward.

Moreover, referring to the reflection intensity (Y) of the SCI of FIG. 15, it may be confirmed that, in case that the thickness H1 of the capping layer 700 is less than 0.8 μm, the reflection intensity (Y) of the SCI is reduced, compared to case that the thickness H1 of the capping layer 700 is 0 or greater than 0.8 μm.

Referring to FIG. 16, it may be confirmed through the optical analysis image that, as the thickness H1 of the capping layer 700 decreases, the halo is formed wider and the intensity of the light forming the halo weakens and becomes blurred. For example, it may be confirmed that, in case that the thickness H1 of the capping layer 700 is greater than 0.85 μm, the halo is densely formed in the central portion and the intensity of the corresponding portion becomes stronger and clearer. This may mean that unintended light L is exposed to the outside, resulting in a deterioration in optical characteristics.

Moreover, referring to the diffraction analysis image of FIG. 16, it may be confirmed that, as the thickness H1 of the capping layer 700 decreases, the diffraction pattern is formed wider and the intensity of the light forming the diffraction pattern weakens and becomes blurred. For example, it may be confirmed that, in case that the thickness H1 of the capping layer 700 is greater than 0.85 μm, the diffraction pattern is densely formed and the intensity of the corresponding portion becomes stronger and clearer. This may mean that unintended light L is exposed to the outside, resulting in a deterioration in optical characteristics.

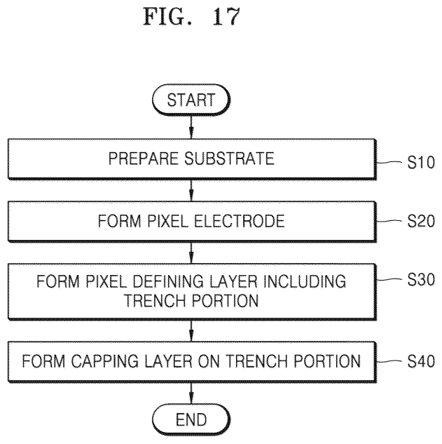

FIG. 17 is a flowchart of a method of manufacturing a display device, according to an embodiment.

Hereinafter, for convenience of explanation, contents which are the same as provided above or may be easily applied by those of ordinary skill in the art are omitted or briefly described.

Referring to FIG. 17, a method of manufacturing the display device 1, according to an embodiment, may include preparing the substrate 100, forming the pixel electrode 211, and forming the pixel defining layer 1170.

The preparing of the substrate 100 (an operation S10) may include preparing the substrate 100 including a glass material or a polymer resin.

The forming of the pixel electrode 211 (an operation S20) may include forming the pixel electrode 211 on the substrate 100. For example, the forming of the pixel electrode 211 (the operation S20) may include forming the pixel layer PXL on the substrate 100.

Between the preparing of the substrate 100 (the operation S10) and the forming of the pixel electrode 211 (the operation S20), the method may further include forming various layers between the substrate 100 and the pixel electrode 211.

The forming of the pixel defining layer 1170 (an operation S30) may include forming the pixel defining layer 1170, of which at least a portion overlaps the pixel electrode 211. The pixel defining layer 1170 may be formed to have the opening OP1 which exposes the central portion of the pixel electrode 211.

The forming of the pixel defining layer 1170 (the operation S30) may include forming the trench portion OP2.

The forming of the trench portion OP2 may include forming the trench portion OP2 recessed in a direction toward the pixel electrode 211 at a position overlapping at least a portion of the pixel electrode 211 spaced apart from the central portion.

The forming of the trench portion OP2 may be performed through a photomask.

For example, the forming of the trench portion OP2 may be performed by using a photomask in which the full-tone dark area FTDKA is formed at a position which overlaps the trench portion OP2.

In other embodiments, the forming of the trench portion OP2 may be performed by using the photomask M1 described above with reference to FIG. 8.

In an embodiment, the method of manufacturing the display device 1, according to the disclosure, may further include forming the capping layer 700 (an operation S40).

The forming of the capping layer 700 (the operation S40) may include forming the capping layer 700 on the trench portion OP2.

In an embodiment, the forming of the capping layer 700 (the operation S40) may include forming the capping layer 700 to cover the entire area of the pixel electrode 211 exposed by the trench portion OP2. In an embodiment, the forming of the capping layer 700 (the operation S40) may include forming the capping layer 700 to cover at least a portion of the second pixel defining layer 1172.

For example, the forming of the capping layer 700 (the operation S40) may be performed by using a photomask including the half-tone dark area HTDKA.

In other embodiments, the forming of the capping layer 700 (the operation S40) may be performed by using the photomask M2 described above with reference to FIG. 10C.

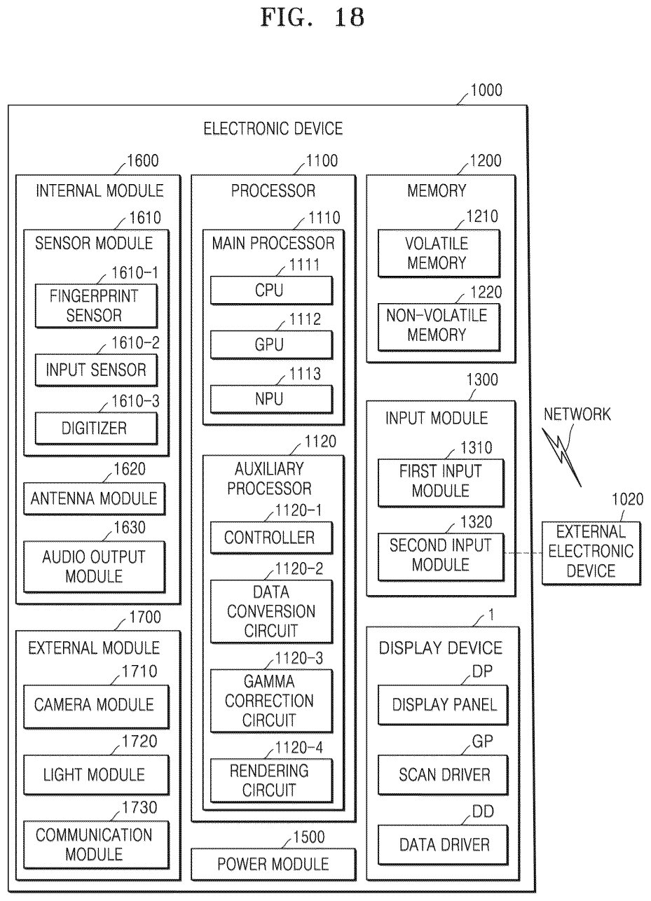

FIG. 18 is a block diagram of an electronic device 1000 according to embodiments.

Referring to FIG. 18, the electronic device 1000 may output a variety of information through a display device 1 within an operating system. The display device 1 may be the display device illustrated in and described with reference to FIGS. 1 to 14C. In case that a processor 1100 executes an application stored in a memory 1200, the display device 1 may provide application information to a user through a display panel DP.

The processor 1100 may obtain external input through an input module 1300 or a sensor module 1610 and execute an application corresponding to the external input. For example, in case that the user selects a camera icon displayed on the display panel DP, the processor 1100 may obtain user input through an input sensor 1610-2 and activate a camera module 1710. The processor 1100 may transmit, to the display device 1, image data corresponding to a captured image obtained through the camera module 1710. The display device 1 may display an image corresponding to the captured image on the display panel DP.

As another example, in case that personal information authentication is performed on the display device 1, a fingerprint sensor 1610-1 may obtain input fingerprint information as input data. The processor 1100 may compare the input data obtained through the fingerprint sensor 1610-1 with authentication data stored in the memory 1200 and execute an application based on a comparison result. The display device 1 may display information executed according to logics of the application on the display panel DP.

As another example, in case that the user selects a music streaming icon displayed on the display device 1, the processor 1100 may obtain user input through the input sensor 1610-2 and activate a music streaming application stored in the memory 1200. In case that a music execution command is input in the music streaming application, the processor 1100 may activate an audio output module 1630 to provide, to the user, audio information corresponding to the music execution command.

The operation of the electronic device 1000 has been briefly described. Hereinafter, the configuration of the electronic device 1000 is described in detail. Some components of the electronic device 1000 described below may be integrated and provided as one component, and one component may be separated into two or more components.

Referring to FIG. 18, the electronic device 1000 may communicate with an external electronic device 1020 over a network (e.g., a short-range wireless communication network or a long-range wireless communication network). According to an embodiment, the electronic device 1000 may include the processor 1100, the memory 1200, the input module 1300, the display device 1, a power module 1500, an internal module 1600, and an external module 1700. According to an embodiment, at least one of the components described above may be omitted from the electronic device 1000, or one or more other components may be added to the electronic device 1000. According to an embodiment, some components described above (e.g., the sensor module 1610, an antenna module 1620, or the audio output module 1630) may be integrated into another component (e.g., the display device 1).

The processor 1100 may execute software to control at least one other component (e.g., a hardware or software component) of the electronic device 1000 connected to the processor 1100 and perform various data processing or operations. According to an embodiment, as at least part of data processing or operations, the processor 1100 may store commands or data received from another component (e.g., the input module 1300, the sensor module 1610, or a communication module 1730) in a volatile memory 1210, process the commands or data stored in the volatile memory 1210, and store resulting data in a non-volatile memory 1220.

The processor 1100 may include one or more processors and may include a main processor 1110 and an auxiliary processor 1120. The main processor 1110 may include at least one of a central processing unit (CPU) 1111 or an application processor (AP). The main processor 1110 may further include at least one of a graphic processing unit (GPU) 1112, a communication processor (CP), or an image signal processor (ISP). The main processor 1110 may further include a neural processing unit (NPU) 1113. The NPU 1113 is a processor specialized in processing an artificial intelligence model. The artificial intelligence model may be generated through machine learning. The artificial intelligence model may include a plurality of artificial neural network layers. The artificial intelligence model may be a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more thereof, but the disclosure is not limited to the above example. The artificial intelligence model may additionally or alternatively include a software structure in addition to the hardware structure. At least two of the processing units and processors described above may be implemented as a single integrated configuration (e.g., a single chip), or the processing units and processors described above may be implemented as independent configurations (e.g., a plurality of chips).

The auxiliary processor 1120 may include a controller 1120-1. The controller 1120-1 may include an interface conversion circuit and a timing control circuit. The controller 1120-1 may receive an image signal from the main processor 1110, convert the data format of the image signal to match the interface specification with the display device 1, and output the image data. The controller 1120-1 may output various control signals required to drive the display device 1.

The auxiliary processor 1120 may further include the controller 1120-1, a data conversion circuit 1120-2, a gamma correction circuit 1120-3, a rendering circuit 1120-4, or the like. The data conversion circuit 1120-2 may receive image data from the controller 1120-1, compensate for the image data so that the image is displayed at a desired luminance according to characteristics of the electronic device 1000 or a user's settings, or convert the image data so as to reduce power consumption or compensate for afterimages. The gamma correction circuit 1120-3 may convert image data or gamma reference voltages so that the image displayed on the electronic device 1000 has desired gamma characteristics. The rendering circuit 1120-4 may receive image data from the controller 1120-1 and render the image data by taking into account the pixel layout of the display panel DP applied to the electronic device 1000. At least one of the data conversion circuit 1120-2, the gamma correction circuit 1120-3, or the rendering circuit 1120-4 may be integrated into another component (e.g., the main processor 1110 or the controller 1120-1). At least one of the data conversion circuit 1120-2, the gamma correction circuit 1120-3, or the rendering circuit 1120-4 may be integrated into a data driver DD described below.

The memory 1200 may store various data used by at least one component of the electronic device 1000 (e.g., the processor 1100 or the sensor module 1610) and input data or output data for commands related thereto. The memory 1200 may include at least one of the volatile memory 1210 or the non-volatile memory 1220.

The input module 1300 may receive commands or data to be used in the components of the electronic device 1000 (e.g., the processor 1100, the sensor module 1610, or the audio output module 1630) from the outside of the electronic device 1000 (e.g., a user or an external electronic device 1020).

The input module 1300 may include a first input module 1310 to which commands or data are input from the user and a second input module 1320 to which commands or data are input from the external electronic device 1020. The first input module 1310 may include a microphone, a mouse, a keyboard, a key (e.g., a button), or a pen (e.g., a passive pen or an active pen). The second input module 1320 may support a designated protocol which is connectable to the external electronic device 1020 in a wired or wireless manner. According to an embodiment, the second input module 1320 may include a high definition multimedia interface (HDMI), a universal serial bus (USB) interface, a secure digital (SD) card interface, or an audio interface. The second input module 1320 may include a connector which is physically connectable to the external electronic device 1020, for example, an HDMI connector, a USB connector, an SD card connector, or an audio connector (e.g., a headphone connector).

The display device 1 may provide visual information to the user. The display device 1 may include the display panel DP, a scan driver GP, and a data driver DD. The display device 1 may further include a window, a chassis, and a bracket so as to protect the display panel DP.

The display panel DP may further include an emission driver. The emission driver may output an emission control signal to the display panel DP in response to the control signal received from the controller 1120-1. The emission driver may be formed separately from the scan driver GP or may be integrated into the scan driver GP.

The scan driver GP may receive a control signal from the controller 1120-1 and output scan signals to the display panel DP in response to the control signal. For example, the control signal, which is generated by the controller 1120-1 and transmitted to the scan driver GP, may be a scan input signal for controlling the scan driver GP. The scan input signal may be an input signal which is applied to switching elements included in stages of the scan driver GP.

The data driver DD may receive a control signal from the controller 1120-1, convert image data into analog voltages (e.g., data voltages) in response to the control signal, and then output the data voltages to the display panel DP. For example, the control signal, which is generated by the controller 1120-1 and transmitted to the data driver DD, may be a data input signal for controlling the data driver DD.

The data driver DD may be integrated into another component (e.g., the controller 1120-1). The functions of the interface conversion circuit and the timing control circuit of the controller 1120-1 may be integrated into the data driver DD.

The controller 1120-1 may generate a clock signal required to drive the scan driver GP. Each stage of the scan driver GP may operate based on the clock signal corresponding to each stage.

The scan driver GP may generate the scan signal based on the scan input signal, the clock signal, and a scan input voltage. The scan signal may be transmitted to a pixel circuit, and a thin-film transistor included in the pixel circuit may be driven based on the scan signal. The scan signal may be transmitted to a gate included in the pixel circuit.

The display device 1 may further include an emission driver and a voltage generation circuit. The voltage generation circuit may output various voltages required to drive the display panel DP.

The power module 1500 may supply power to the components of the electronic device 1000. The power module 1500 may generate a gate driving voltage (e.g., a gate high voltage or a gate low voltage) required to drive the scan driver GP.

For example, the power module 1500 may refer to a power generator, a power supply, or the like. For example, the power module 1500 may include a battery which charges a power supply voltage. The battery may include a non-rechargeable primary battery, a rechargeable secondary battery, or a fuel cell.

For example, the power module 1500 may include a power management integrated circuit (PMIC). The PMIC may provide optimized power to each of the modules described above and modules described below.

For example, the power module 1500 may include a wireless power transmission/reception member electrically connected to the battery. The wireless power transmission/reception member may include a plurality of coil-type antenna radiators.

The electronic device 1000 may further include the internal module 1600 and the external module 1700. The internal module 1600 may include the sensor module 1610, the antenna module 1620, and the audio output module 1630. The external module 1700 may include the camera module 1710, a light module 1720, and the communication module 1730.

The sensor module 1610 may detect input by the user's body or input by the pen of the first input module 1310 and generate an electrical signal or a data value corresponding to the input. The sensor module 1610 may include at least one of the fingerprint sensor 1610-1, the input sensor 1610-2, or a digitizer 1610-3.

The fingerprint sensor 1610-1 may generate a data value corresponding to the user's fingerprint. The fingerprint sensor 1610-1 may include at least one of an optical fingerprint sensor or a capacitive fingerprint sensor.

The input sensor 1610-2 may generate a data value corresponding to coordinate information of the input by the user's body or the input by the pen. The input sensor 1610-2 may generate a data value based on an amount of change in electrostatic capacitance by the input. The input sensor 1610-2 may detect input by the passive pen, or may transmit and receive data to and from the active pen.

The input sensor 1610-2 may also measure biometric signals, such as blood pressure, moisture, or body fat. For example, in case that the user touches a part of his/her body to a sensor layer or a sensing panel and does not move for a certain time, the input sensor 1610-2 may detect biometric signals based on a change in electric field caused by the part of his/her body and output information desired by the user to the display device 1.

The digitizer 1610-3 may generate a data value corresponding to coordinate information input by the pen. The digitizer 1610-3 may generate a data value based on an amount of change in electromagnetism by the input. The digitizer 1610-3 may detect input by the passive pen, or may transmit and receive data to and from the active pen.

At least one of the fingerprint sensor 1610-1, the input sensor 1610-2, or the digitizer 1610-3 may be implemented as the sensor layer formed on the display panel DP through a continuous process. The fingerprint sensor 1610-1, the input sensor 1610-2, and the digitizer 1610-3 may be disposed above the display panel DP. One of the fingerprint sensor 1610-1, the input sensor 1610-2, and the digitizer 1610-3, for example, the digitizer 1610-3 may be disposed below the display panel DP.

At least two of the fingerprint sensor 1610-1, the input sensor 1610-2, or the digitizer 1610-3 may be integrated into a single sensing panel through the same process. In case that at least two of the fingerprint sensor 1610-1, the input sensor 1610-2, or the digitizer 1610-3 are integrated into a single sensing panel, the sensing panel may be disposed between the display panel DP and the window disposed above the display panel DP. According to an embodiment, the sensing panel may be disposed on the window and the location of the sensing panel is not particularly limited.

At least one of the fingerprint sensor 1610-1, the input sensor 1610-2, or the digitizer 1610-3 may be embedded into the display panel DP. For example, at least one of the fingerprint sensor 1610-1, the input sensor 1610-2, or the digitizer 1610-3 may be formed simultaneously through the process of forming the components (e.g., the light-emitting element, the transistor, or the like) included in the display panel DP.

In some embodiments, the sensor module 1610 may generate an electrical signal or a data value corresponding to the internal or external state of the electronic device 1000. The sensor module 1610 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illumination sensor.

The antenna module 1620 may include one or more antennas which transmit signals or power to the outside or receive signals or power from the outside. According to an embodiment, the communication module 1730 may transmit and receive signals to and from an external electronic device through an antenna suitable for a communication scheme. An antenna pattern of the antenna module 1620 may be integrated into the component of the display device 1 (e.g., the display panel DP) or the input sensor 1610-2.

The audio output module 1630 is a device which outputs audio signals to the outside of the electronic device 1000. The audio output module 1630 may include, for example, a speaker used for general purposes, such as multimedia playback or recording playback, and a receiver used exclusively for phone reception. According to an embodiment, the receiver may be formed integrally with or separately from the speaker. An audio output pattern of the audio output module 1630 may be integrated into the display device 1.

The camera module 1710 may capture still images and moving images. According to an embodiment, the camera module 1710 may include one or more lenses, image sensors, or image signal processors. The camera module 1710 may further include an IR camera capable of measuring the presence or absence of the user, the user's location, the user's line of sight, or the like.

The light module 1720 may provide light. The light module 1720 may include a light-emitting diode or a xenon lamp. The light module 1720 may operate in conjunction with the camera module 1710 or may operate independently.

The communication module 1730 may support establishment of a wired or wireless communication channel between the electronic device 1000 and the external electronic device 1020 and may support performance of communication through the established communication channel. The communication module 1730 may include one or all of a wireless communication module (e.g., a cellular communication module, a short-range wireless communication module, or a global navigation satellite system (GNSS) communication module) and a wired communication module (e.g., a local area network (LAN) communication module or a power line communication module). The communication module 1730 may communicate with the external electronic device 1020 over a short-range wireless communication network (e.g., Bluetooth, wireless fidelity (WiFi) direct, or infrared data association (IrDA)), or a long-range wireless communication network (e.g., a cellular network, the Internet, or a computer network (e.g., a LAN or a wide area network (WAN)). Various types of the communication module 1730 described above may be implemented as a single chip or separate chips.

The input module 1300, the sensor module 1610, the camera module 1710, and the like may be used to control the operation of the display device 1 in conjunction with the processor 1100.

The processor 1100 may output commands or data to the display device 1, the audio output module 1630, the camera module 1710, or the light module 1720, based on input data received from the input module 1300. For example, the processor 1100 may generate image data in response to input data applied through the mouse or the active pen and output the image data to the display device 1, or may generate command data in response to input data and output the command data to the camera module 1710 or the light module 1720. In case that no input data is received from the input module 1300 for a certain time, the processor 1100 may switch the operation mode of the electronic device 1000 to a low power mode or a sleep mode so as to reduce power consumption of the electronic device 1000.

The processor 1100 may output commands or data to the display device 1, the audio output module 1630, the camera module 1710, or the light module 1720, based on sensing data received from the sensor module 1610. For example, the processor 1100 may compare authentication data applied by the fingerprint sensor 1610-1 with authentication data stored in the memory 1200 and execute an application based on a comparison result. The processor 1100 may execute commands or output corresponding image data to the display device 1, based on sensing data detected by the input sensor 1610-2 or the digitizer 1610-3. In case that the temperature sensor is included in the sensor module 1610, the processor 1100 may receive temperature data related to the measured temperature from the sensor module 1610 and further perform luminance correction or the like on the image data, based on the temperature data.

The processor 1100 may receive, from the camera module 1710, measurement data related to the presence or absence of the user, the user's location, the user's line of sight, or the like. The processor 1100 may further perform luminance correction or the like on the image data, based on the measurement data. For example, the processor 1100 which determines the presence or absence of the user through input from the camera module 1710 may output, to the display device 1, image data in which luminance is corrected through the data conversion circuit 1120-2 or the gamma correction circuit 1120-3.

Some of the components described above may be connected to each other through a communication scheme between peripheral devices (e.g., a bus, a general purpose input/output (GPIO), a serial peripheral interface (SPI), a mobile industry processor interface (MIPI), or an ultra path interconnect (UPI) link) and may exchange signals (e.g., commands or data) with each other. The processor 1100 may communicate with the display device 1 through a prearranged interface. For example, the processor 1100 may use any one of the communication schemes described above. However, the disclosure is not limited thereto.

The electronic device 1000 according to various embodiments may be various types of devices. The electronic device 1000 may include, for example, at least one of portable communication devices (e.g., smartphones), computer devices, portable multimedia devices, portable medical devices, cameras, wearable devices, or home appliances. The electronic device 1000 according to an embodiment is not limited to the devices described above.

In an embodiment, the display device 1 may include the display panel DP and the scan driver GP. The controller 1120-1 may generate a scan input signal required to drive the scan driver GP. The power module 1500 may generate a scan input voltage required to drive the scan driver GP under the control by the processor or the controller 1120-1. For example, the scan input voltage may be a gate driving voltage.

The display panel DP may be divided into a display area where a pixel circuit is disposed and a peripheral area surrounding the display area. As described above, an area where an image is displayed may be the display area, and an area outside the display area and where an image is not displayed may be the peripheral area.

The scan driver GP may be disposed in the peripheral area and may receive the scan input signal from the controller 1120-1 and the scan input voltage from the power module 1500. The scan driver GP may generate the scan signal or output the scan signal, based on the scan input signal and/or the scan input voltage. The scan signal may be transmitted from the scan driver GP to the pixel circuit.

In an embodiment, the scan driver GP may include at least one capacitor. The at least one capacitor may include an electrode and another electrode. For example, the electrode may be a signal line configured to transmit at least one of the scan input signal or the scan input voltage. For example, the electrode may be at least a portion of the signal line configured to transmit at least one of the scan input signal or the scan input voltage. The signal line is only an example and may be a wiring through which the scan input voltage is transmitted.

For example, the other electrode may overlap the electrode. The other electrode may overlap the signal line configured to transmit at least one of the scan input signal or the scan input voltage. For example, the other electrode may overlap at least a portion of the signal line configured to transmit at least one of the scan input signal or the scan input voltage.

In an embodiment, the peripheral area may include a wiring layout area in which wirings are disposed and a circuit layout area in which at least one transistor is disposed between the display area and the wiring disposition area. For example, at least one capacitor may be disposed in the wiring layout area. The at least one capacitor may be disposed in the wiring layout area.

According to the disclosure, the display device 1, which has improved optical characteristics by guiding external light or reflected light reflected from the opposite electrode 251 to the anti-reflection member 600, the method of manufacturing the display device 1, and the electronic device 1000 including the display device 1 may be provided.

Moreover, according to the disclosure, the display device 1, in which the occurrence rate of dark spots is reduced, the method of manufacturing the display device 1, and the electronic device 1000 including the display device 1 may be provided.

According to one or more embodiments, a display device with improved optical characteristics, a method of manufacturing the display device, and an electronic device including the display device may be provided.

However, such an effect is only an example, and the effect of the disclosure is not limited thereto.

However, the effects according to the disclosure are not limited thereto, and those of ordinary skill in the art will appreciate that various effects may be derived from the embodiments described above.

Each of the embodiments described above may be implemented independently, but it is obvious that the structure of each of the embodiments may be applied in combination to other embodiments.

The disclosure has been described with reference to the embodiments illustrated in the drawings, but this is only an example. It will be understood by those of ordinary skill in the art that various modifications and equivalents may be made thereto. Accordingly, the true technical protection scope of the disclosure should be defined by the technical spirit of the appended claims.

Specific executions described in the embodiments are only embodiments, which do not limit the scope of the embodiments in any way. In some embodiments, when there is no specific mention such as “essential,” “important,” etc., it may not be a necessary component for the application of the disclosure.

The use of the term “the” and similar demonstratives in the specification of the embodiments (in particular, the claims) is to be construed to cover both the singular and the plural. In some embodiments, when a range is described in the embodiments, it includes the inventive concept to which individual values within the range are applied (unless otherwise indicated herein). This is the same as stating each individual value constituting the above range in the detailed description. Finally, operations constituting methods according to embodiments may be performed in any suitable order unless otherwise indicated herein or otherwise clearly contradicted by context. The embodiments are not necessarily limited by the order of description of operations. The use of any and all examples or exemplary terms provided in the embodiments is simply intended to describe the embodiments in detail, and the scope of the embodiments is not limited by the examples or exemplary terms unless otherwise claimed. In some embodiments, it will be understood by those of ordinary skill in the art that various modifications, combinations and changes may be made according to design conditions and factors within the scope of the appended claims or equivalents thereof.

What is claimed is:

1. A display device comprising:
a substrate;
a pixel electrode disposed on the substrate; and
a pixel defining layer defining an opening exposing a central portion of the pixel electrode and comprising a trench portion recessed in a direction toward the pixel electrode,
wherein the pixel defining layer comprises:
a first pixel defining layer adjacent to the opening; and
a second pixel defining layer spaced apart from the first pixel defining layer.

2. The display device of claim 1, wherein the pixel defining layer comprises a black pixel defining layer.

3. The display device of claim 1, wherein the trench portion is disposed to expose at least a portion of the pixel electrode.

4. The display device of claim 1, wherein the pixel electrode is disposed to overlap an entire area of the first pixel defining layer.

5. The display device of claim 1, wherein the first pixel defining layer is formed in a shape in which a width of the first pixel defining layer becomes narrower in a direction away from the pixel electrode.

6. The display device of claim 1, wherein an inclination angle of a portion of the first pixel defining layer adjacent to the opening is greater than an inclination angle of a portion of the first pixel defining layer adjacent to the trench portion.

7. The display device of claim 1, wherein an inclination angle of a portion of the first pixel defining layer adjacent to the trench portion is 11° to 45°.

8. The display device of claim 1, wherein the pixel electrode is disposed to overlap at least a portion of the second pixel defining layer.

9. The display device of claim 1, wherein the first pixel defining layer and the second pixel defining layer are spaced apart from each other by a distance of 2.0 μm to 2.2 μm.

10. The display device of claim 1, further comprising an anti-reflection member disposed on the pixel defining layer to overlap at least a portion of the trench portion.

11. An electronic device comprising:
a substrate;
a pixel electrode disposed on the substrate;
a pixel defining layer defining an opening exposing a central portion of the pixel electrode and comprising a trench portion recessed in a direction toward the pixel electrode; and
a capping layer disposed on the trench portion.

12. The electronic device of claim 11, wherein the capping layer comprises a material which is different from a material of the pixel defining layer.

13. The electronic device of claim 11, wherein the trench portion is disposed to expose at least a portion of the pixel electrode.

14. The electronic device of claim 13, wherein the capping layer is disposed to cover the exposed portion of the pixel electrode.

15. The electronic device of claim 11, wherein the pixel defining layer comprises:
a first pixel defining layer adjacent to the opening; and
a second pixel defining layer spaced apart from the first pixel defining layer.

16. The electronic device of claim 15, wherein the capping layer is disposed not to cover an uppermost end of the first pixel defining layer.

17. The electronic device of claim 15, wherein the capping layer is disposed to cover an uppermost end of the second pixel defining layer.

18. The electronic device of claim 15, wherein the capping layer overlaps the first pixel defining layer by greater than 0 μm and less than or equal to 2.0 μm.

19. The electronic device of claim 11, wherein a thickness from the pixel electrode to a lowermost end of the capping layer is 0.4 μm to 0.8 μm.

20. The electronic device of claim 11, further comprising an anti-reflection member disposed on the pixel defining layer to overlap at least a portion of the trench portion.
